(19) United States
(12) Patent Application Publication
(10) Pub. No.: US 2024/0032359 A1
(43) Pub. Date: Jan. 25, 2024

(54) DISPLAY PANEL

(71) Applicant: Samsung Display Co., Ltd., Yongin-si (KR)

(72) Inventors: SUNKWUN SON, Yongin-si (KR); DONG HEE SHIN, Yongin-si (KR)

(73) Assignee: Samsung Display Co., Ltd., Yongin-si (KR)

(21) Appl. No.: 18/312,147

(22) Filed: May 4, 2023

(30) Foreign Application Priority Data
Jul. 25, 2022 (KR) 10-2022-0091801

(51) Int. Cl. H10K 59/131; H10K 59/80; H10K 59/123

(52) U.S. Cl. CPC H10K 59/131; H10K 59/8792; H10K 59/123; H10K 2102/311

(57) ABSTRACT

A display panel includes a base layer including an active area and a peripheral area disposed adjacent to the active area, a compensation electrode disposed in the base layer and including a compensation pattern disposed in the active area and a contact pattern connected to the compensation pattern and disposed in the peripheral area, at least one transistor disposed on the base layer, and a light emitting element including a first electrode connected to the at least one transistor, a second electrode disposed on the first electrode, and a light emitting pattern disposed between the first electrode and the second electrode. The second electrode is disposed in the active area and the peripheral area, and is electrically connected to the contact pattern in the peripheral area.

### CROSS-REFERENCE TO RELATED APPLICATION(S)

This application claims priority to and benefits of Korean Patent Application No. 10-2022-0091801 under 35 U.S.C. § 119, filed on Jul. 25, 2022, in the Korean Intellectual Property Office (KIPO), the entire contents of which are incorporated herein by reference.

### BACKGROUND

### 1. Technical Field

The disclosure herein relates to a display panel and a display device having improved display quality.

### 2. Description of the Related Art

Display devices are activated in response to electrical signals. The display devices may be composed of various layers, such as a display panel for displaying images or an input sensing layer for sensing external inputs. Components included in the display devices may be electrically connected via variously arranged signal lines.

### SUMMARY

The disclosure provides a display device including a light emitting element capable of receiving a uniform power voltage over an entire active area.

An embodiment of the disclosure provides a display panel that may include a base layer including an active area and a peripheral area disposed adjacent to the active area, a compensation electrode disposed in the base layer and including a compensation pattern disposed in the active area, and a contact pattern electrically connected to the compensation pattern and disposed in the peripheral area, at least one transistor disposed on the base layer, and a light emitting element including a first electrode electrically connected to the at least one transistor, a second electrode disposed on the first electrode, and a light emitting pattern disposed between the first electrode and the second electrode. The second electrode may be disposed in the active area and the peripheral area, and may be electrically connected to the contact pattern in the peripheral area.

In an embodiment, the contact pattern may surround the active area in a plan view.

In an embodiment, the compensation pattern may include first patterns each extending in a first direction and spaced apart from each other in a second direction intersecting the first direction.

In an embodiment, the compensation pattern may further include second patterns each extending in the second direction, intersecting the first patterns, and spaced apart from each other in the first direction.

In an embodiment, an end of each of the first patterns may be electrically connected to a first side of the contact pattern, which extends in the second direction, another end of each of the first patterns may be electrically connected to a second side of the contact pattern, which extends in the second direction and is spaced apart from the first side in the first direction, an end of each of the second patterns may be electrically connected to a third side of the contact pattern, which extends in the first direction and is electrically connected to an end of each of the first side and the second side of the contact pattern, and another end of each of the second patterns may be electrically connected to a fourth side of the contact pattern, which extends in the first direction and is electrically connected to another end of each of the first side and the second side of the contact pattern.

In an embodiment, the compensation pattern may further include pattern openings defined by the first patterns and the second patterns, and disposed in the active area.

In an embodiment, the contact pattern may include a main pattern surrounding the active area in a plan view, and a sub pattern protruding from a portion of the main pattern in a direction away from the active area.

In an embodiment, a width of the sub pattern in a direction the portion of the main pattern extends may decrease along the direction the sub pattern protrudes.

In an embodiment, the base layer may include a first organic layer, a first barrier layer, a second organic layer, and a second barrier layer, which are sequentially stacked.

In an embodiment, the compensation electrode may be disposed on the first barrier layer and be covered by the second organic layer.

In an embodiment, each of the first organic layer and the second organic layer may include polyimide.

In an embodiment, each of the first barrier layer and the second barrier layer may include silicon oxide.

In an embodiment, the compensation electrode may include a lower layer, an intermediate layer, and an upper layer, which are sequentially stacked, and a thickness of the intermediate layer may be greater than a thickness of the lower layer and a thickness of the upper layer in a thickness direction of the base layer.

In an embodiment, each of the lower layer and the upper layer may include titanium, and the intermediate layer may include aluminum.

In an embodiment, the display panel may further include a dummy electrode directly contacting the second electrode in the peripheral area. The dummy electrode and the first electrode may be disposed on a same layer.

In an embodiment, the display panel may further include a first intermediate insulating layer disposed on the transistor, and a first connection electrode disposed on the first intermediate insulating layer in the active area, and electrically connected to the first electrode and the at least one transistor.

In an embodiment, the display panel may further include a first compensation connection electrode disposed in the peripheral area, and electrically connected to the dummy electrode and the compensation electrode. The first compensation connection electrode and the first connection electrode may be disposed on a same layer.

In an embodiment, the display panel may further include a second intermediate insulating layer disposed on the first intermediate insulating layer, and a second connection electrode disposed on the second intermediate insulation layer in the active area, and electrically connected to the first electrode and the first connection electrode.

In an embodiment, the display panel may further include a second compensation connection electrode disposed in the peripheral area, and electrically connected to the dummy electrode and the first compensation connection electrode. The second compensation connection electrode and the second connection electrode may be disposed on a same layer.

In an embodiment, the at least one transistor may include a source, an active, a drain, and a gate overlapping the active in a plan view, and the display panel may further include a light blocking pattern overlapping the active in a plan view and disposed on the base layer.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain principles of the disclosure. In the drawings:

FIG. 1A is a perspective view of a display device according to an embodiment of the disclosure;

FIG. 1B is a perspective view of a curved display device according to an embodiment of the disclosure;

FIG. 1C is a perspective view of a folded display device according to an embodiment of the disclosure;

FIG. 2 is a schematic cross-sectional view of a display device according to an embodiment of the disclosure;

FIG. 3A is a schematic block diagram of a display panel according to an embodiment of the disclosure;

FIG. 3B is a schematic diagram of an equivalent circuit of a pixel according to an embodiment of the disclosure;

FIG. 4 is a schematic cross-sectional view of a display module according to an embodiment of the disclosure;

FIG. 5 is a schematic cross-sectional view of a display device according to an embodiment of the disclosure;

FIG. 6 is a schematic diagram of an equivalent circuit of a pixel according to an embodiment of the disclosure;

FIG. 7 is a schematic cross-sectional view of a display module according to an embodiment of the disclosure;

FIG. 8 is a plan view of a compensation electrode disposed on a base layer according to an embodiment of the disclosure;

FIG. 9 is a schematic cross-sectional view of a display panel, taken along line I′-I of FIG. 8 according to an embodiment of the disclosure;

FIG. 10 is a schematic cross-sectional view of a display panel, taken along line I′-I of FIG. 8 according to an embodiment of the disclosure;

FIG. 11 is a schematic cross-sectional view of a display panel, taken along line I′-I of FIG. 8 according to an embodiment of the disclosure;

FIG. 12 is a schematic cross-sectional view of a display panel, taken along line I′-I of FIG. 8 according to an embodiment of the disclosure;

FIG. 13 is a plan view of a compensation electrode disposed on a base layer according to an embodiment of the disclosure; and

FIG. 14 is a plan view of a compensation electrode disposed on a base layer according to an embodiment of the disclosure.

### DETAILED DESCRIPTION OF THE EMBODIMENTS

In the description, when an element, such as a layer, is referred to as being “on”, “connected to”, or “coupled to” another element or layer, it may be directly on, connected to, or coupled to the other element or layer or intervening elements or layers may be present. When, however, an element or layer is referred to as being “directly on”, “directly connected to”, or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

Like reference numerals refer to like elements. In the drawings, the thickness, the ratio, and the dimensions of elements are exaggerated for an effective description of technical contents. In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

It will be understood that, although the terms first, second, etc. may be used herein to describe various elements, these elements should not be limited by these terms. These terms are only used to distinguish one element from another element. For example, a first element may be referred to as a second element, and similarly, a second element may be referred to as a first element without departing from the teachings of the disclosure. The singular forms are intended to include the plural forms as well, unless the context clearly indicates otherwise.

Also, terms of “below”, “on lower side”, “above”, “on upper side”, or the like may be used to describe the relationships of the components illustrated in the drawings. The terms are used as a relative concept and are described with reference to the direction indicated in the drawings.

It should be understood that the terms “comprise”, or “have” are intended to specify the presence of stated features, integers, steps, operations, elements, components, or combinations thereof in the disclosure, but do not preclude the presence or addition of one or more other features, integers, steps, operations, elements, components, or combinations thereof.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined, all terms (including technical and scientific terms) used herein have the same meaning as commonly understood by one of ordinary skill in the art to which the disclosure belongs. Also, terms, such as those defined in commonly used dictionaries, should be interpreted as having a meaning that is consistent with their meaning in the context of the relevant art and should not be interpreted in an idealized or overly formal sense unless expressly so defined herein.

Hereinafter, embodiments of the disclosure will be described with reference to the accompanying drawings.

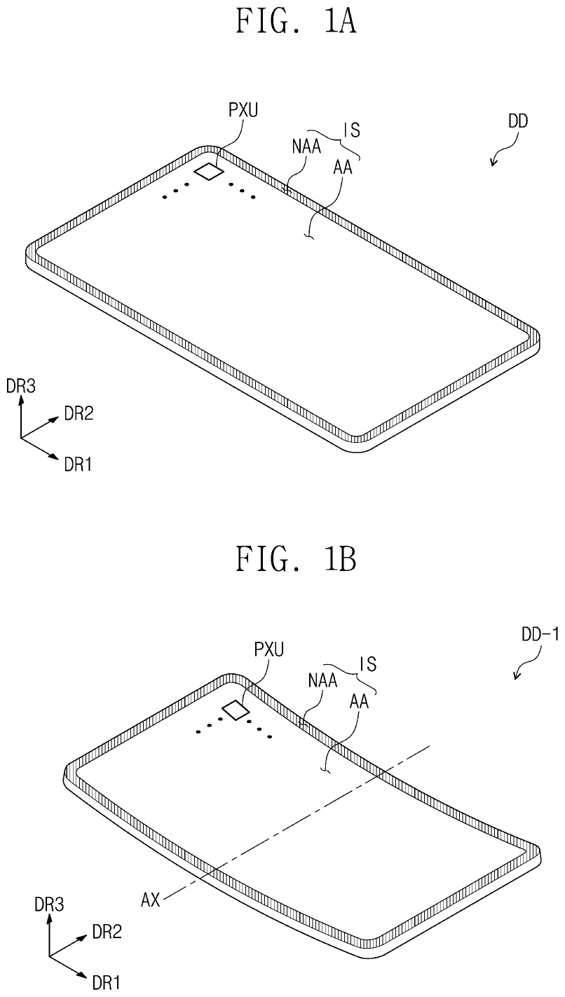

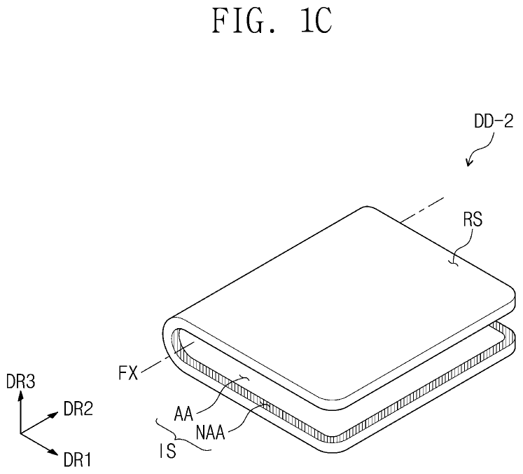

FIG. 1A is a perspective view of a display device according to an embodiment of the disclosure. FIG. 1B is a perspective view of a curved display device according to an embodiment of the disclosure. FIG. 1C is a perspective view of a folded display device according to an embodiment of the disclosure.

Display devices DD, DD-1, and DD-2 shown in FIGS. 1A to 1C may be devices activated according to electrical signals. For example, the display devices DD, DD-1, and DD-2 may be a mobile phone, a tablet, a car navigation system, a game console, or a wearable device, but are not limited thereto.

Referring to FIG. 1A, the display device DD may display images through a display surface IS. The display surface IS may include an active area AA displaying images and a peripheral area NAA disposed adjacent to the active area AA. The display device DD may sense external inputs through the active area AA.

The active area AA according to an embodiment may include a plane defined by a first direction DR1 and a second direction DR2. A thickness direction of the display device DD may be defined as a third direction DR3 perpendicular to each of the first direction DR1 and the second direction DR2. Therefore, a front surface (or an upper surface) and a rear surface (or a lower surface) of members constituting the display device DD may be defined with respect to the third direction DR3.

The peripheral area NAA may surround at least a portion of the active area AA. The peripheral area NAA may be a region defined by a bezel pattern printed on a window WM which will be described below or provided in the form of a tape. The bezel pattern may include a color.

Although FIG. 1A shows the peripheral area NAA surrounding four sides of the active area AA, the disclosure is not limited thereto, and the peripheral area NAA may not be disposed on at least one side of the active area AA or the peripheral area NAA may be omitted.

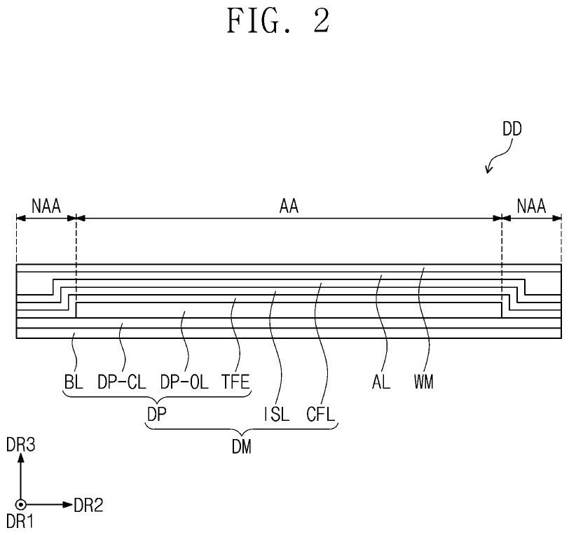

The display device DD may display images through the display surface IS. An upper surface of a member disposed on an uppermost side of the display device DD may be defined as the display surface IS. According to the disclosure, an upper surface of the window WM shown in FIG. 2 may be defined as the display surface IS of the display device DD. Although an edge of the display device DD is shown in a rounded shape in FIG. 1A, the disclosure is not limited thereto.

Referring to FIG. 1B, the display device DD-1 according to an embodiment may be curved along the first direction DR1 with respect to a virtual axis AX extending in the second direction DR2. Accordingly, the display device DD-1 may be curved with a curvature (predetermined or selectable). However, the disclosure is not limited thereto, and the virtual axis AX may extend in the first direction DR1, or the display device DD-1 may be curved with respect to multiple axes extending in different directions.

It is shown that a unit pixel PXU is disposed in the active area AA of FIGS. 1A and 1B. The unit pixel PXU may include at least two pixels providing different light. For example, the unit pixel PXU may be a region in which pixels providing green, red, and blue light are disposed. The light emitting area, shape, and arrangement of each of the pixels included in the unit pixel PXU are not limited. For example, the light emitting area of each of the pixels included in the unit pixel PXU may be different. Each of the light emitting regions may have a circular or polygonal shape in a plan view.

Referring to FIG. 1C, the display device DD-2 according to an embodiment may be folded with respect to a virtual folding axis FX extending in the second direction DR2. Accordingly, the display device DD-2 according to an embodiment may repeat folding and unfolding operations with respect to the folding axis FX.

In case that the display device DD-2 is folded with respect to the folding axis FX, the display surfaces IS may be folded to face each other, and a rear surface RS of the display device DD-2 may be viewed. Such a folding operation may be defined as “in-folding”. In the display device DD-2 including an in-folding operation, the folding axis FX may be defined on the display surface IS.

However, the folding operation of the display device DD-2 is not limited to in-folding, and the folding axis according to an embodiment may be defined on the rear surface RS of the display device DD-2. In case that the display device DD-2 is folded with respect to the folding axis, the rear surfaces RS may be folded to face each other, and the display surface IS of the display device DD-2 may be viewed. Such a folding operation may be defined as “out-folding”.

In the display device according to an embodiment, the display device may have a multi-folding structure in which a portion is in-folded and another portion is out-folded, or a portion is in-folded with a first curvature and another portion is in-folded with a second curvature smaller than the first curvature, but the disclosure is not limited thereto.

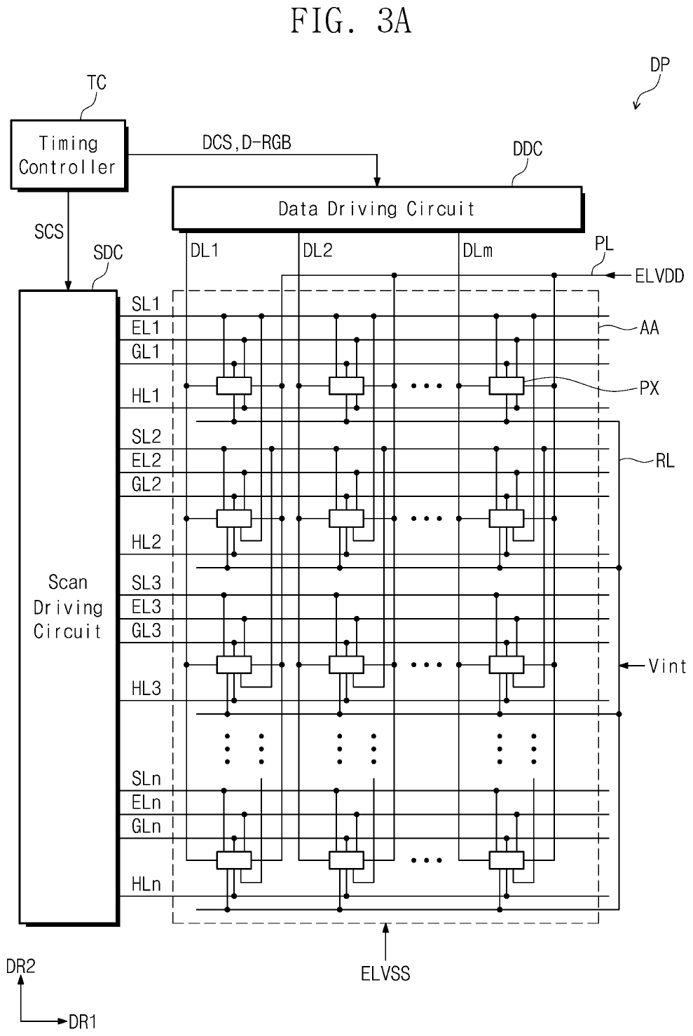

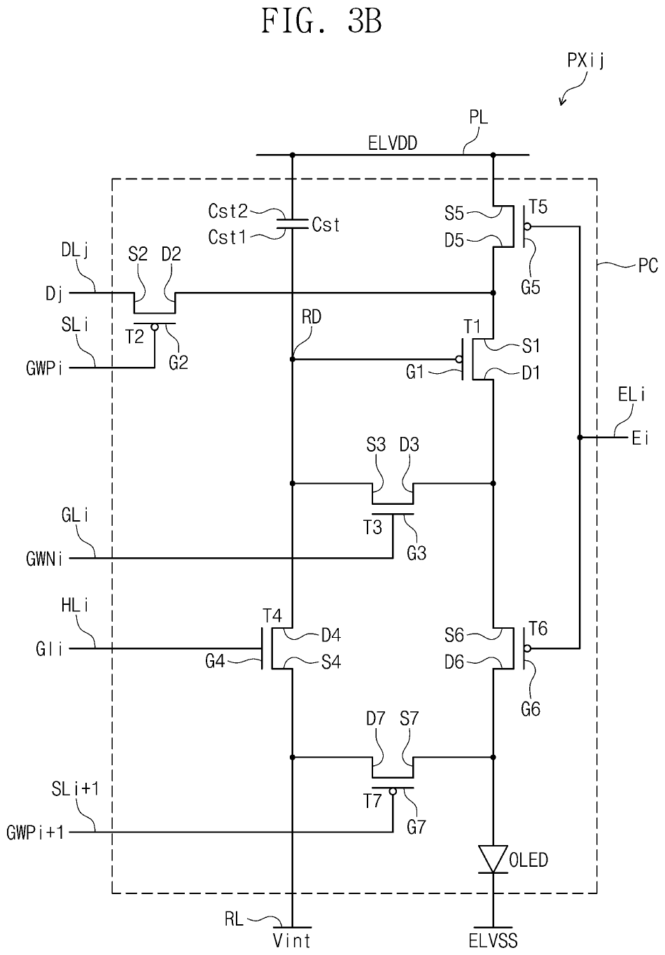

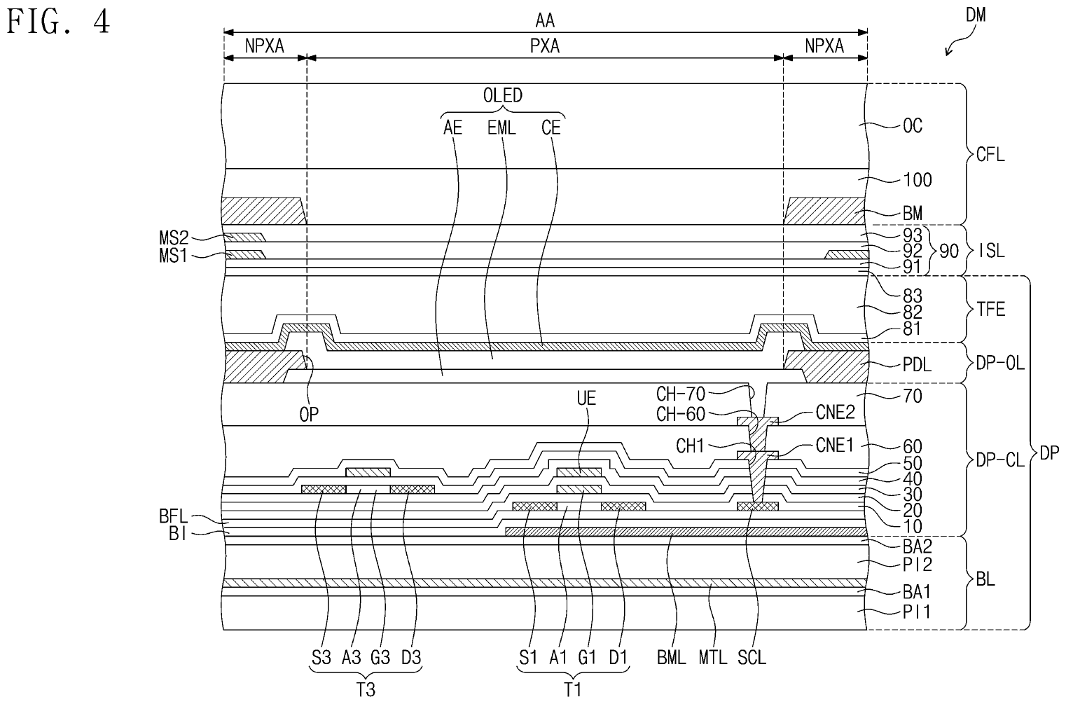

FIG. 2 is a schematic cross-sectional view of a display device according to an embodiment of the disclosure. FIG. 3A is a schematic block diagram of a display panel according to an embodiment of the disclosure. FIG. 3B is a schematic diagram of an equivalent circuit of a pixel according to an embodiment of the disclosure. FIG. 4 is a schematic cross-sectional view of a display module according to an embodiment of the disclosure.

Referring to FIG. 2, the display device DD may include a window WM and a display module DM. The display module DM according to an embodiment may include a display panel DP, an input sensing layer ISL, and a color filter layer CFL. The window WM and the display module DM may be bonded by an adhesive layer AL disposed between the window WM and the display module DM. The adhesive layer AL may include at least one of an optically clear adhesive, an optically clear adhesive resin, and a pressure sensitive adhesive (PSA).

A front surface of the window WM may correspond to the display surface IS of the display device DD. The window WM may include an optically transparent insulating material. For example, the window WP may include a glass or a plastic. The window WM may have a multi-layer structure or a single-layer structure. For example, the window WM may include multiple plastic films bonded by an adhesive, or a glass substrate and a plastic film, which are bonded by an adhesive.

The display panel DP may be configured to substantially generate images. The display panel DP may be a light emitting display panel, and for example, the display panel DP may be an organic light emitting display panel, an inorganic light emitting display panel, an organic-inorganic light emitting display panel, a quantum dot display panel, a micro LED display panel, or a nano LED display panel. The display panel DP may include a base layer BL, a circuit layer DP-CL, an element layer DP-OL, and a thin film encapsulation layer TFE.

The base layer BL may be a base layer on which other components of the display panel DP are disposed. The base layer BL may be formed of a flexible material. The base layer BL according to an embodiment may include a multi-layer structure in which at least one organic/inorganic layer is stacked each other.

The circuit layer DP-CL may be disposed on the base layer BL. The circuit layer DP-CL may include at least one insulating layer and a circuit element. The insulating layer may include at least one inorganic film and at least one organic film. The circuit element may include a pixel driving circuit included in each of the pixels for generating images. The element layer DP-OL may include a light emitting element connected to the circuit layer DP-CL.

A compensation electrode capable of storing a power voltage may be included in the base layer BL according to the disclosure so that the power voltage provided to a light emitting element is uniformly provided to the entire active area AA. Descriptions thereof will be provided below.

The thin film encapsulation layer TFE may seal the element layer DP-OL. The thin film encapsulation layer TFE may include at least one organic layer and inorganic layers sealing the organic layer. The inorganic layer may include an inorganic material and may protect the element layer DP-OL from moisture/oxygen. The organic layer may include an organic material and may protect the element layer DP-OL from foreign materials such as dust particles.

The input sensing layer ISL may be disposed on the display panel DP. The input sensing layer ISL may sense external inputs applied from the outside. The external inputs may be a user's inputs. The user's inputs may include various types of external inputs such as a part of a user's body, light, heat, pen, or pressure.

For example, the input sensing layer ISL may be formed on the display panel DP through a roll-to-roll process. The input sensing layer ISL may be ‘directly disposed’ on the display panel DP. ‘Being directly disposed’ may indicate that a third component is not disposed between the input sensing layer ISL and the display panel DP. For example, a separate adhesive member may not be disposed between the input sensing layer ISL and the display panel DP. According to an embodiment, the input sensing layer ISL may be bonded to the display panel DP by an adhesive member. The adhesive layer may include a general adhesive or a gluing agent.

The color filter layer CFL may be disposed on the input sensing layer ISL. The color filter layer CFL may include an anti-reflection layer that reduces reflectance of external light incident from the outside of the display device DD. The color filter layer CFL may include a color filter capable of selectively transmitting light corresponding to the light provided from the display panel DP.

Referring to FIG. 3A, the display panel DP according to an embodiment may include a timing controller TC, a scan driving circuit SDC, a data driving circuit DDC, and pixels PX disposed in the active area AA.

The timing controller TC may receive input image signals, convert data format of the input image signals to meet interface specifications with the scan driving circuit SDC, and generate image data D-RGB. The timing controller TC may output image data D-RGB and various control signals DCS and SCS.

The scan driving circuit SDC may receive a scan control signal SCS from the timing controller TC. The scan control signal SCS may include a vertical start signal for initiating the operation of the scan driving circuit SDC, a clock signal for determining output timing of signals, and the like. The scan driving circuit SDC may generate multiple scan signals and sequentially outputs the signals to corresponding signal lines SL1 to SLn and GL1 to GLn. The scan driving circuit SDC may generate multiple light emitting control signals in response to the scan control signal SCS, and output the light emitting control signals to corresponding signal lines EL1 to ELn.

Although FIG. 3A shows that multiple scan signals and multiple light emitting control signals are output from one scan driving circuit SDC, the disclosure is not limited thereto. In an embodiment of the disclosure, multiple scan driving circuits may divide, generate, and output scan signals, and divide, generate, and output multiple light emitting control signals. In an embodiment of the disclosure, a driving circuit generating and outputting multiple scan signals and a driving circuit generating and outputting multiple light emitting control signals may be separate and distinct.

The data driving circuit DDC may receive the data control signal DCS and the image data D-RGB from the timing controller TC. The data driving circuit DDC may convert the image data D-RGB into data signals, and output the data signals to multiple data lines DL1 to DLm which will be described below. The data signals may be analog voltages corresponding to the grayscale value of the image data D-RGB.

The display panel DP may include a first group of scan lines SL1 to SLn, a second group of scan lines GL1 to GLn, a third group of scan lines HL1 to HLn, light emitting lines EL1 to ELn, data lines DL1 to DLm, a first voltage line PL, a second voltage line RL, and multiple pixels PX. The first group of scan lines SL1 to SLn, the second group of scan lines GL1 to GLn, the third group of scan lines HL1 to HLn, and the light emitting lines EL1 to ELn may extend in the first direction DR1 and may be arranged in the second direction DR2 intersecting the first direction DR1.

The data lines DL1 to DLm may insulatively cross the first group of scan lines SL1 to SLn, the second group of scan lines GL1 to GLn, the third group of scan lines HL1 to HLn, and the light emitting lines EL1 to ELn. Each of the pixels PX may be connected to a corresponding one of the signal lines. A connection relationship between the pixels PX and the signal lines may change according to configuration of the driving circuit of the pixels PX.

The first voltage line PL may receive a first power voltage ELVDD. The second voltage line RL may receive an initialization voltage Vint. The initialization voltage Vint may have a lower level than the first power voltage ELVDD. A second power voltage ELVSS may be applied to a light emitting element OLED (see FIG. 4). The second power voltage ELVSS may have a lower level than the first power voltage ELVDD.

The second power voltage ELVSS may be commonly provided to the pixels PX. The pixel initially receiving the second power voltage ELVSS and the pixel receiving the second power voltage ELVSS later may receive the second power voltage ELVSS having different values due to an IR drop phenomenon.

For example, a pixel disposed adjacent to a border between the active area AA and the peripheral area NAA and a pixel disposed at the center of the active area AA may be provided with the second power voltage ELVSS having different magnitudes. The fact that the IR drop phenomenon prevents the pixels disposed in the active area AA from being provided with a uniform second power voltage ELVSS may cause defects due to difference in luminance in the active area AA.

The pixels PX may include multiple groups generating different color light. For example, the pixels PX may include red pixels generating red color light, green pixels generating green color light, and blue pixels generating blue color light. A light emitting element of the red pixel, a light emitting element of the green pixel, and a light emitting element of the blue pixel may include emission layers of different materials. Pixels providing different light may constitute the unit pixel PXU shown in FIGS. 1A and 1B.

The pixel circuit PC (see FIG. 3B) may include multiple transistors and a capacitor electrically connected to the transistors. At least one of the scan driving circuit SDC or the data driving circuit DDC may include multiple transistors formed through a same process as the pixel circuit PC (see FIG. 3B).

The signal lines, the pixels PX, the scan driving circuit SDC, and the data driving circuit DDC which are described above may be formed on the base layer BL (see FIG. 2) by performing photolithography multiple times. Multiple insulating layers may be formed on the base layer BL by performing deposition or coating multiple times. The insulating layers may be thin films disposed to correspond to the pixels PX, and some of the insulating layers may include an insulating pattern overlapping only a particular conductive pattern. The insulating layers may include organic layers and/or inorganic layers.

FIG. 3B shows a schematic diagram of an equivalent circuit of one pixel PXij included in the display panel DP. The pixel PXij according to an embodiment may be connected to an i-th scan line SLi among the first group of scan lines SL1 to SLn, and may be connected to a j-th data line DLj among the data lines DL1 to DLm.

The pixel PXij may include a pixel circuit PC and a light emitting element OLED. In the embodiment, the pixel circuit PC may include first to seventh transistors T1 to T7 and a capacitor Cst. The embodiment describes the first transistor T1, the second transistor T2, and the fifth transistor T5 to the seventh transistor T7 as P-type transistors, and the third transistor T3 and the fourth transistor T4 as N-type transistors. However, the disclosure is not limited thereto, and the first to seventh transistors T1 to T7 may be implemented as either a P-type transistor or an N-type transistor. In an embodiment of the disclosure, at least one of the first to seventh transistors T1 to T7 may be omitted.

In the embodiment, the first transistor T1 may be a driving transistor, and the second transistor T2 may be a switching transistor. The capacitor Cst may be connected between the first voltage line PL receiving the first power voltage ELVDD and a reference node RD. The capacitor Cst may include a first capacitor electrode Cst1 connected to the reference node RD and a second capacitor electrode Cst2 connected to the first voltage line PL.

The first transistor T1 may be connected between the first voltage line PL and an electrode of the light emitting element OLED. The source S1 of the first transistor T1 may be electrically connected to the first voltage line PL. Another transistor may be disposed or omitted between the source S1 of the first transistor T1 and the first voltage line PL.

The drain D1 of the first transistor T1 may be electrically connected to the first electrode AE (see FIG. 4) of the light emitting element OLED. Another transistor may be disposed or omitted between the drain D1 of the first transistor T1 and the first electrode AE (see FIG. 4) of the light emitting element OLED. The gate G1 of the first transistor T1 may be electrically connected to the reference node RD.

The second transistor T2 may be connected between the j-th data line DLj and the source S1 of the first transistor T1. The source S2 of the second transistor T2 may receive a j-th data signal Dj from the j-th data line DLj, and the drain D2 of the second transistor T2 may be electrically connected to the source S1 of the first transistor T1. In the embodiment, the gate G2 of the second transistor T2 may receive an i-th scan signal GWPi from the i-th scan line SLi of the first group.

The third transistor T3 may be connected between the reference node RD and the drain D1 of the first transistor T1. The drain D3 of the third transistor T3 may be electrically connected to the drain D1 of the first transistor T1, and the source S3 of the third transistor T3 may be electrically connected to the reference node RD. In the embodiment, the gate G3 of the third transistor T3 may receive an i-th scan signal GWNi from the i-th scan line GLi of the second group.

The fourth transistor T4 may be connected between the reference node RD and the second voltage line RL. The drain D4 of the fourth transistor T4 may be electrically connected to the reference node RD, and the source S4 of the fourth transistor T4 may be electrically connected to the second voltage line RL. In the embodiment, the gate G4 of the fourth transistor T4 may be electrically connected to the i-th scan line HLi of the third group.

The fifth transistor T5 may be connected between the first voltage line PL and the source S1 of the first transistor T1. The source S5 of the fifth transistor T5 may be electrically connected to the first voltage line PL, and the drain D5 of the fifth transistor T5 may be electrically connected to the source S1 of the first transistor T1. The gate G5 of the fifth transistor T5 may receive the i-th light emitting signal Ei from the i-th light emitting line ELi.

The sixth transistor T6 may be connected between the drain D1 of the first transistor T1 and the light emitting element OLED. The source S6 of the sixth transistor T6 may be electrically connected to the drain D1 of the first transistor T1, and the drain D5 of the sixth transistor T6 may be electrically connected to the first electrode AE (see FIG. 4) of the light emitting element OLED. The gate G6 of the sixth transistor T6 may be electrically connected to the i-th light emitting line ELi.

The seventh transistor T7 may be connected between the drain D6 of the sixth transistor T6 and the second voltage line RL. The source S7 of the seventh transistor T7 may be electrically connected to the drain D6 of the sixth transistor T6, and the drain D7 of the seventh transistor T7 may be electrically connected to the second voltage line RL. The gate G7 of the seventh transistor T7 may receive an i+1th scan signal GWPi+1 from an i+1th scan line SLi+1 of the first group.

FIG. 4 shows a schematic cross-sectional view of a display module DM including the pixel PX described with reference to FIGS. 2 to 3B.

The display module DM according to an embodiment may include a display panel DP, an input sensing layer ISL, and a color filter layer CFL. The display panel DP may include a base layer BL, a circuit layer DP-CL, an element layer DP-OL, and a thin film encapsulation layer TFE.

The display panel DP may further include functional layers such as an anti-reflection layer and a refractive index control layer. The circuit layer DP-CL may include multiple insulating layers and a circuit element. The insulating layers may include an organic layer and/or an inorganic layer. An insulating layer, a semiconductor layer, and a conductive layer may be formed through processes such as coating or deposition. The insulating layer, the semiconductor layer, and the conductive layer may be selectively patterned through a photolithography method, and a semiconductor pattern, a conductive pattern, a signal line, and the like may be formed.

The base layer BL according to an embodiment may include a first organic layer PI1, a first barrier layer BA1, a second organic layer PI2, and a second barrier layer BA2 which are sequentially stacked along an emitting direction of light generated from the light emitting element OLED.

Each of the first and second organic layers PI1 and PI2 may include an organic material. For example, the first and second organic layers PI1 and PI2 may include at least one of polyimide (PI), polyethylene naphthalate, polyethylene terephthalate, polyarylate, polycarbonate, polyetherimide, and polyethersulfone.

The first and second barrier layers BA1 and BA2 may include an inorganic material. For example, the first and second barrier layers BA1 and BA2 may include at least one of aluminum oxide, titanium oxide, silicon oxide, silicon nitride, silicon oxynitride, zirconium oxide, and hafnium oxide. The first and second barrier layers BA1 and BA2 may prevent oxygen or moisture introduced through the base layer BL from penetrating into the pixels PX.

The display panel DP according to an embodiment may include a compensation electrode MTL disposed in the base layer BL. The compensation electrode MTL may be connected to the second electrode CE of the light emitting element OLED in the peripheral area NAA (see FIG. 2). Descriptions thereof will be provided below.

A light blocking pattern BML may be disposed on the base layer BL. The light blocking pattern BML may serve a function such as shielding. The light blocking pattern BML may block an electric potential due to polarization between insulating layers disposed on the light blocking pattern BML from affecting the first to seventh transistors T1 to T7 (see FIG. 3B). The light blocking pattern BML according to an embodiment may include molybdenum.

The barrier layer BI may be disposed on the base layer BL and may cover the light blocking pattern BML. The barrier layer BI may include an inorganic material. For example, the barrier layer BI may include at least one of aluminum oxide, titanium oxide, silicon oxide, silicon nitride, silicon oxynitride, zirconium oxide, and hafnium oxide.

The buffer layer BFL may be disposed on the barrier layer BI. The buffer layer BFL may be provided as multi-layers each including an inorganic material. A lower layer of the buffer layer BFL may include silicon oxide and an upper layer thereof may include silicon nitride. However, the disclosure is not limited thereto, and the buffer layer BFL may be provided as a single-layer, and may include at least one of aluminum oxide, titanium oxide, silicon oxide, silicon nitride, silicon oxynitride, zirconium oxide, and hafnium oxide. The buffer layer BFL may reduce surface energy of the base layer BL so that the pixels PX are stably formed on the base layer BL.

The first semiconductor pattern of the first transistor T1 may be disposed on the buffer layer BFL. The first semiconductor pattern may include a silicon semiconductor. The first semiconductor pattern may include polysilicon. However, the disclosure is not limited thereto, and the first semiconductor pattern may include amorphous silicon.

FIG. 4 only shows a portion of the first semiconductor pattern, and the first semiconductor pattern may be further disposed in another region of the pixel PXij (see FIG. 3B). The first semiconductor pattern may have different electrical properties according to a doping. The first semiconductor pattern may include a doped region and a non-doped region. The doped region may be doped with an N-type dopant or a P-type dopant. A P-type transistor may include a doped region which is doped with a P-type dopant. A N-type transistor may include a doped region which is doped with a N-type dopant.

The source S1, the active μl, and the drain D1 of the first transistor T1 may be formed from the first semiconductor pattern. The source S1 and the drain D1 of the first transistor T1 may be formed to be spaced apart from each other with the active μl therebetween.

The connection signal line SCL may be disposed on the buffer layer BFL. The connection signal line SCL may be connected to the sixth transistor T6 (see FIG. 3B) in a plan view.

A first insulating layer 10 may be disposed on the buffer layer BFL to cover the first semiconductor pattern and the connection signal line SCL. The first insulating layer may be an inorganic layer and/or an organic layer, and have a single-layered or multi-layered structure. The first insulating layer 10 may include at least one of aluminum oxide, titanium oxide, silicon oxide, silicon nitride, silicon oxynitride, zirconium oxide, and hafnium oxide.

An insulating layer of the circuit layer DP-CL which will be described below may be an inorganic layer and/or an organic layer, and has a single-layered or multi-layered structure. The inorganic layer may include at least one of the materials described above.

A gate G1 of the first transistor T1 may be disposed on the first insulating layer 10. The gate G1 may be a portion of a metal pattern. The gate G1 of the first transistor T1 may overlap the active μl of the first transistor T1 in a plan view. In the process of doping of the first semiconductor pattern, the gate G1 of the first transistor T1 may function as a mask.

A second insulating layer 20 may be disposed on the first insulating layer 10 to cover the gate G1 of the first transistor T1. The second insulating layer 20 may include at least one of aluminum oxide, titanium oxide, silicon oxide, silicon nitride, silicon oxynitride, zirconium oxide, and hafnium oxide.

An upper electrode UE may be disposed on the second insulating layer 20. The upper electrode UE may overlap the gate G1 of the first transistor T1 in a plan view. The upper electrode UE may be a portion of a metal pattern or a portion of a doped semiconductor pattern. A portion of the gate G1 of the first transistor T1 and the upper electrode UE overlapping the portion may constitute the capacitor Cst (see FIG. 3B). In an embodiment, the upper electrode UE may be omitted.

Although the second insulating layer 20 is shown to be disposed over the entire active area AA, the disclosure is not limited thereto, and the second insulating layer 20 may be an insulating pattern. In case that the second insulating layer 20 is an insulating pattern, the upper electrode UE may be disposed on the insulating pattern. The upper electrode UE may serve as a mask to form an insulating pattern from the second insulating layer 20.

Although not shown separately, the first capacitor electrode Cst1 (see FIG. 3B), the second capacitor electrode Cst2 (see FIG. 3B) of the capacitor Cst (see FIG. 3B), the gate G1, and the upper electrode UE may be formed through a same process. The first capacitor electrode Cst1 may be disposed on the first insulating layer 10. The first capacitor electrode Cst1 (see FIG. 3B) may be electrically connected to the gate G1 of the first transistor T1. The first capacitor electrode Cst1 (see FIG. 3B) and the gate G1 of the first transistor T1 may be integral with each other.

A third insulating layer 30 may be disposed on the second insulating layer 20 to cover the upper electrode UE. In the embodiment, the third insulating layer 30 may include at least one of aluminum oxide, titanium oxide, silicon oxide, silicon nitride, silicon oxynitride, zirconium oxide, and hafnium oxide.

Although not shown separately, the sources S2, S5, S6, and S7 and the drains D2, D5, D6, and D7 of the second, fifth, sixth, and seventh transistors T2, T5, T6, and T7 (see FIG. 3B) may be formed through a same process as the source S1 and the drain D1 of the first transistor T1, and the gates G2, G5, G6, and G7 of the second, fifth, sixth, and seventh transistors T2, T5, T6, and T7 (see FIG. 3B) may be formed through a same process as the gate G1 of the first transistor T1. Patterns formed through a same process may be disposed on a same layer.

The second semiconductor pattern may be disposed on the third insulating layer 30. The second semiconductor pattern may include a metal oxide. The second semiconductor pattern may include a crystalline or amorphous oxide semiconductor. For example, the oxide semiconductor may include at least one of indium-tin oxide (ITO), indium-gallium-zinc oxide (IGZO), zinc oxide (ZnO), indium-zinc oxide (IZnO), zinc-indium oxide (ZIO), indium oxide (InO), titanium oxide (TiO), indium-zinc-tin oxide (IZTO), and zinc-tin oxide (ZTO).

The source S3, the active A3, and the drain D3 of the third transistor T3 may be formed from the second semiconductor pattern. The source S3 and the drain D3 of the third transistor T3 may include metal reduced from a metal oxide semiconductor. The source S3 and the drain D3 of the third transistor T3 may have a thickness (predetermined or selectable) from an upper surface of the second semiconductor pattern and include a metal layer including the reduced metal.

A fourth insulating layer 40 may be disposed on the third insulating layer 30 to cover the second semiconductor pattern. In the embodiment, the fourth insulating layer 40 may include a silicon oxide layer and a silicon nitride layer. The fourth insulating layer 40 may include multiple silicon oxide layers and silicon nitride layers that are alternately stacked each other.

The gate G3 of the third transistor T3 may be disposed on the fourth insulating layer 40. The gate G3 may be a portion of a metal pattern. The gate G3 of the third transistor T3 may overlap the active A3 of the third transistor T3 in a plan view.

Although FIG. 4 shows that the fourth insulating layer 40 is disposed over the entire active area AA, the disclosure is not limited thereto, and the fourth insulating layer 40 may be an insulating pattern. The gate G3 of the third transistor T3 may be disposed on the insulating pattern. In the embodiment, the gate G3 and the insulating pattern may have a same shape in a plan view.

A fifth insulating layer 50 may be disposed on the fourth insulating layer 40 to cover the gate G3 of the third transistor T3. In the embodiment, the fifth insulating layer 50 may include a silicon oxide layer and a silicon nitride layer. The fifth insulating layer 50 may include multiple silicon oxide layers and silicon nitride layers that are alternately stacked each other.

Although not shown separately, the source S4 and the drain D4 of the fourth transistor T4 (see FIG. 3B) and the source S3 and the drain D3 of the third transistor T3 may be formed through a same process, and the gate G4 of the fourth transistor T4 (see FIG. 3B) and the gate G3 of the third transistor T3 may be formed through a same process.

At least one insulating layer may be further disposed on the fifth insulating layer 50. As in the embodiment, a sixth insulating layer 60 and a seventh insulating layer 70 may be disposed on the fifth insulating layer 50. The sixth insulating layer 60 and the seventh insulating layer 70 may be organic layers, and may have a single-layer or multi-layer structure. The sixth insulating layer 60 and the seventh insulating layer 70 may be a single polyimide-based resin layer.

The disclosure is not limited thereto, and the sixth insulating layer 60 and the seventh insulating layer 70 may include at least one of an acryl-based resin, a methacrylate-based resin, polyisoprene, a vinyl-based resin, an epoxy-based resin, a urethane-based resin, a cellulose-based resin, a siloxane-based resin, a polyamide-based resin, and a perylene-based resin.

A first connection electrode CNE1 may be disposed on the fifth insulating layer 50. The first connection electrode CNE1 may be connected to the connection signal line SCL through a contact hole CH1 passing through the first to fifth insulating layers 10 to 50.

A second connection electrode CNE2 may be disposed on the sixth insulating layer 60. The second connection electrode CNE2 is connected to the first connection electrode CNE1 through a second contact hole CH-60 passing through the sixth insulating layer 60.

The seventh insulating layer 70 may be disposed on the sixth insulating layer 60 to cover the second connection electrode CNE2.

Components of the light emitting element OLED may be disposed on the seventh insulating layer 70. The first electrode AE of the light emitting element OLED may be disposed on the seventh insulating layer 70. A pixel defining film PDL may be disposed on the seventh insulating layer 70. An opening OP exposing at least a portion of the first electrode AE may be defined in the pixel defining film PDL. In the embodiment, the pixel defining film PDL may have a color and include a light absorbing material. For example, the color of the pixel defining film PDL may be black.

The first to seventh transistors T1 to T7 (see FIG. 3B) connected to the light emitting element OLED may constitute one pixel PXij (see FIG. 3B).

The opening OP of the pixel defining film PDL may define a light emitting region PXA. For example, the pixels PXij (see FIG. 3B) of the display panel DP may be arranged in a regular manner in a plan view. A region in which the pixels PXij (see FIG. 3B) are disposed may be defined as an active area AA, and the active area AA may include multiple light emitting regions PXA and a non-light emitting region NPXA adjacent to the light emitting regions PXA. The non-light emitting region NPXA may surround the light emitting regions PXA.

The first electrode AE may be disposed on the seventh insulating layer 70. The first electrode AE may be connected to the second connection electrode CNE2 through a third contact hole CH-70 passing through the seventh insulating layer 70.

The light emitting element OLED according to an embodiment may further include a hole control layer (not illustrated) disposed between the first electrode AE and the light emitting pattern EML. The hole control layer may be commonly disposed in the light emitting region PXA and the non-light emitting region NPXA. A common layer such as a hole control layer may be commonly formed in the pixels PXij. The hole control layer may include a hole transport layer and a hole injection layer.

The light emitting pattern EML may be disposed between the first electrode AE and the second electrode CE. The light emitting pattern EML may overlap the opening OP in a plan view. The light emitting pattern EML may be separately formed in each of the pixels PXij.

Although the light emitting pattern EML patterned and disposed in one opening OP is shown as an embodiment, the light emitting pattern EML may be commonly disposed in the pixels PXij, and the light emitting pattern EML may generate white light or blue light. The light emitting pattern EML may have a multi-layer structure.

The light emitting element OLED according to an embodiment may further include an electron control layer (not illustrated) disposed between the second electrode CE and the light emitting pattern EML. The electron control layer may include an electron transport layer and an electron injection layer.

The second electrode CE may be disposed on the light emitting pattern EML. The electron control layer and the second electrode CE may be commonly disposed in the pixels PXij (see FIG. 3B). Accordingly, the second electrode CE according to the disclosure may be disposed over the entire active area AA and peripheral area NAA (see FIG. 2).

The thin film encapsulation layer TFE may be disposed on the second electrode CE. The thin film encapsulation layer TFE may be commonly disposed on the pixels PXij. In the embodiment, the thin film encapsulation layer TFE may cover (e.g., directly cover) the second electrode CE. The thin film encapsulation layer TFE may include a first thin film inorganic layer 81, a thin film organic layer 82, and a second thin film inorganic layer 83. However, the disclosure is not limited thereto, and the thin film encapsulation layer TFE may further include multiple inorganic layers and organic layers.

The first thin film inorganic layer 81 may contact the second electrode CE. The first thin film inorganic layer 81 may prevent external moisture or oxygen from penetrating into the light emitting pattern EML. For example, the first thin inorganic layer 81 may include silicon nitride, silicon oxide, or a combination thereof. The first thin inorganic layer 81 may be formed through a deposition process.

The thin film organic layer 82 may be disposed on the first thin film inorganic layer 81 and contact the first thin film inorganic layer 81. The thin film organic layer 82 may provide a flat surface on the first thin film inorganic layer 81. A curvature formed on an upper surface of the first thin film inorganic layer 81 or particles present on the first thin film inorganic layer 81 may be covered by the thin film organic layer 82 to prevent an upper surface of the first thin film inorganic layer 81 from affecting components formed on the thin film organic layer 82. The thin film organic layer 82 may include an organic material and may be formed through a solution process such as spin coating, slit coating, or inkjet process.

The second thin film inorganic layer 83 may be disposed on the thin film organic layer 82 and cover the thin film organic layer 82. The second thin film inorganic layer 83 may be stably formed on a relatively flat surface compared to being disposed on the first thin film inorganic layer 81. The second thin film inorganic layer 83 may prevent moisture or oxygen from being introduced into the light emitting pattern EML. The second thin film inorganic layer 83 may include silicon nitride, silicon oxide, or a combination thereof. The second thin film inorganic layer 83 may be formed through a deposition process.

The input sensing layer ISL may be directly formed on the thin film encapsulation layer TFE. The input sensing layer ISL may include multiple conductive patterns MS1 and MS2 and sensing insulating layers 90. The sensing insulating layers 90 may include a first sensing insulating layer 91, a second sensing insulating layer 92, and a third sensing insulating layer 93.

The first sensing insulating layer 91 may be disposed on the thin film encapsulation layer TFE. The first conductive patterns MS1 may be disposed on the first sensing insulating layer 91 and covered by the second sensing insulating layer 92. The second conductive patterns MS2 may be disposed on the second sensing insulating layer 92 and covered by the third sensing insulating layer 93.

Each of the conductive patterns MS1 and MS2 may be conductive. Each of the conductive patterns MS1 and MS2 may be provided as a single layer or as multiple layers, but the disclosure is not limited thereto. At least one of the conductive patterns MS1 and MS2 according to the disclosure may be provided as mesh lines in a plan view.

The mesh lines constituting the at least one of the conductive patterns MS1 and MS2 may be spaced apart from the light emitting pattern EML in a plan view. Accordingly, even in case that the input sensing layer ISL is directly formed on the display panel DP, light emitted from the pixels PXij (see FIG. 3B) of the display panel DP may be provided to users without interference with the input sensing layer ISL.

The color filter layer CFL may include a color filter 100, a black matrix BM, and an overcoat layer OC.

The color filter 100 may include a polymer photosensitive resin, a pigment, or a dye. For example, the color filter 100 overlapping the light emitting pattern EML providing blue light may include a blue pigment or dye, the color filter 100 overlapping the light emitting pattern EML providing green light may include a green pigment or dye, and the color filter 100 overlapping the light emitting pattern EML providing red light may include a red pigment or dye.

However, the disclosure is not limited thereto, and the color filter 100 overlapping the light emitting pattern EML providing blue light may not include a pigment or a dye. In case that the color filter does not include a pigment or a dye, the color filter 100 may be transparent, and the color filter 100 may be formed of a transparent photosensitive resin.

The black matrix BM may be disposed between the color filters 100 providing different light. The black matrix BM may be a pattern in black and may be a grid-shaped matrix in a plan view. The black matrix BM may include a black coloring agent. The black coloring agent may include a black dye and/or a black pigment. The black coloring agent may include carbon black, a metal such as chromium, or an oxide thereof.

The overcoat layer OC may be disposed on the color filter 100 and the black matrix BM. The overcoat layer OC may be a layer that covers unevenness generated upon formation of the color filter 100 and the black matrix BM and provides a flat surface. For example, the overcoat layer OC may be a planarization layer. The window WM described in FIG. 2 may be bonded to the overcoat layer OC by the adhesive layer AL.

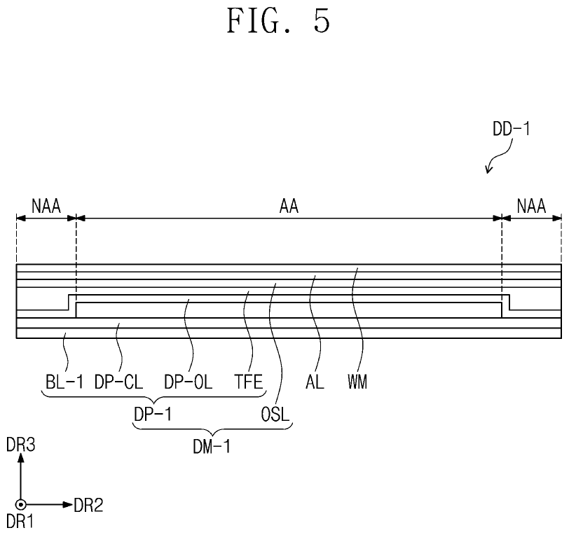

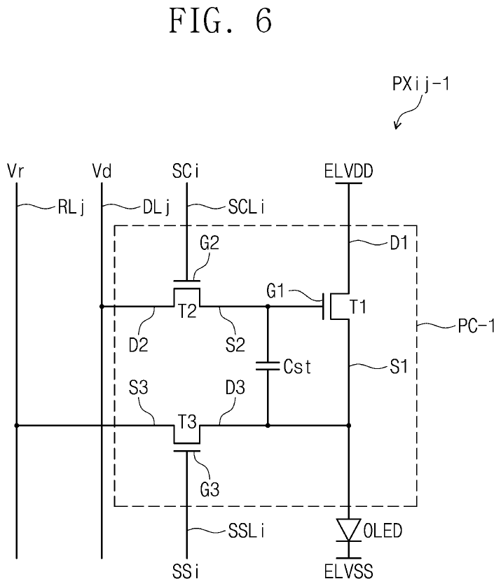

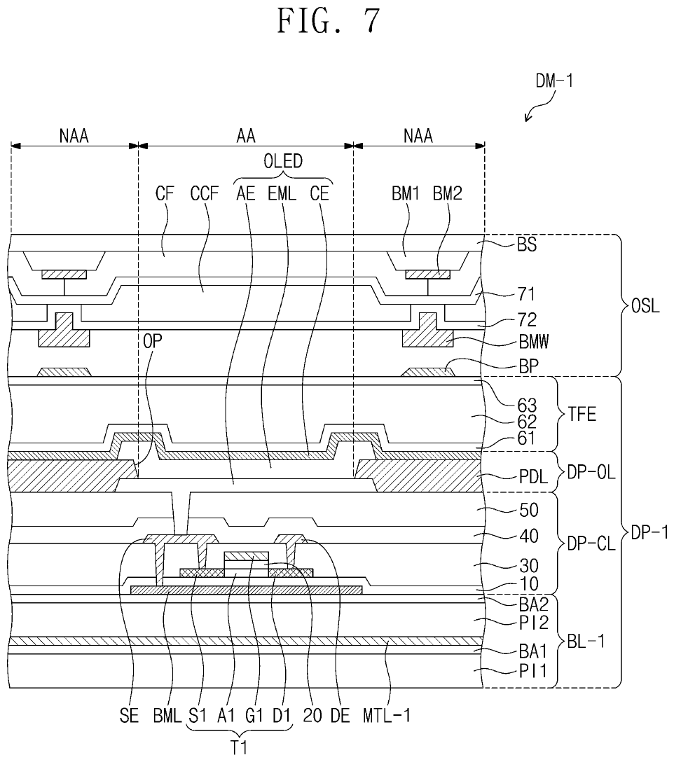

FIG. 5 is a schematic cross-sectional view of a display device according to an embodiment of the disclosure. FIG. 6 is a schematic diagram of an equivalent circuit of a pixel according to an embodiment of the disclosure. FIG. 7 is a schematic cross-sectional view of a display module according to an embodiment of the disclosure.

Referring to FIG. 5, the display device DD-1 may include a window WM and a display module DM-1. The display module DM-1 according to an embodiment may include a display panel DP-1 and a light control layer OSL. The window WM and the display module DM-1 may be bonded by the adhesive layer AL disposed between the window WM and the display module DM-1. Descriptions of the window WM and the adhesive layer AL may be same as the window WM and the adhesive layer AL described with reference to FIG. 2.

The Display panel DP-1 according to an embodiment may be an organic light emitting display panel, an inorganic light emitting display panel, an organic-inorganic light emitting display panel, a quantum dot display panel, a micro LED display panel, or a nano LED display panel. The display panel DP-1 may include a base layer BL, a circuit layer DP-CL, an element layer DP-OL, and a thin film encapsulation layer TFE.

The base layer BL-1 may be a base layer on which other components of the display panel DP-1 are disposed. The base layer BL-1 may be formed of a flexible material. The base layer BL-1 according to an embodiment may include a multi-layer structure in which at least one organic/inorganic layer is stacked each other.

The circuit layer DP-CL may be disposed on the base layer BL-1. The circuit layer DP-CL may include at least one insulating layer and a circuit element. The insulating layer may include at least one inorganic film and at least one organic film. The circuit element may include a pixel driving circuit included in each of the pixels for generating images. The element layer DP-OL may include a light emitting element connected to the circuit layer DP-CL.

A compensation electrode capable of storing a power voltage may be included in the base layer BL-1 according to the disclosure so that the power voltage provided to a light emitting element is uniformly provided to the entire active area AA. Descriptions thereof will be provided below.

The thin film encapsulation layer TFE may seal the element layer DP-OL. The thin film encapsulation layer TFE may include at least one organic layer and inorganic layers sealing the organic layer. The inorganic layer may include an inorganic material and may protect the element layer DP-OL from moisture/oxygen. The organic layer may include an organic material and may protect the element layer DP-OL from foreign materials such as dust particles.

The light control layer OSL may include light control patterns capable of converting optical properties of source light generated from the light emitting element OLED (see FIG. 7), and color filter patterns selectively transmitting light passing through the light control patterns. The light control patterns may include quantum dots.

FIG. 6 shows a schematic diagram of an equivalent circuit of one pixel PXij-1 included in the display panel DP-1. The pixel PXij-1 may include a pixel circuit PC-1 and a light emitting element OLED. The pixel circuit PC-1 may include multiple transistors T1 to T3 and a capacitor Cst.

The transistors T1 to T3 may be formed through a low temperature polycrystalline silicon (LTPS) process or a low temperature polycrystalline oxide (LTPO) process. Each of the first to third transistors T1 to T3 may include a silicon semiconductor and/or an oxide semiconductor. The oxide semiconductor may include a crystalline or amorphous oxide semiconductor, and the silicon semiconductor may include amorphous silicon, polycrystalline silicon, and the like, but the disclosure is not limited thereto.

Hereinafter, the first to third transistors T1 to T3 are described as N-type, but the disclosure is not limited thereto, and each of the first to third transistors T1 to T3 may be a P-type transistor or an N-type transistor according to applied signals. A source and a drain of the P-type transistor may correspond to a drain and a source of the N-type transistor, respectively.

FIG. 6 shows a pixel PXij-1 connected to an i-th scan line SCLi among scan lines, an i-th sensing line SSLi among sensing lines, a j-th data line DLj among data lines, and a j-th initial line RLj among initial lines.

The pixel circuit PC-1 according to an embodiment may include a first transistor T1 (a driving transistor), a second transistor T2 (a switching transistor), a third transistor T3 (a sensing transistor), and a capacitor Cst. However, the pixel circuit PC-1 may further include an additional transistor and an additional capacitor, and the disclosure is not limited thereto.

The light emitting element OLED may be an organic light emitting element or an inorganic light emitting element including the first electrode AE (see FIG. 7) and the second electrode CE (see FIG. 7). The first electrode AE of the light emitting element OLED (see FIG. 7) may receive the first power voltage ELVDD through the first transistor T1, and the second electrode CE of the light emitting element OLED (see FIG. 7) may receive the second power voltage ELVSS. The light emitting element OLED may receive the first power voltage ELVDD and the second power voltage ELVSS to emit light. The second power voltage ELVSS may have a lower level than the first power voltage ELVDD. The second power voltage ELVSS may be commonly provided to pixels. The pixel initially receiving the second power voltage ELVSS and the pixel receiving the second power voltage ELVSS later may receive the second power voltage ELVSS having different values due to an IR drop phenomenon. Such a phenomenon may cause defects due to difference in luminance in the active area AA (see FIG. 5).

The first transistor T1 may include a drain D1 receiving the first power voltage ELVDD, a source S1 connected to the first electrode AE (see FIG. 7) of a light emitting element OLED, and a gate G1 connected to capacitor Cst. The first transistor T1 may control a driving current flowing to the light emitting element OLED from the first power voltage ELVDD in response to voltage values stored in the capacitor Cst.

The second transistor T2 may include a drain D2 connected to the j-th data line DLj, a source S2 connected to the capacitor Cst, and a gate G2 receiving the i-th first scan signal SCi. The second transistor T2 may provide a data voltage Vd to the first transistor T1 in response to the i-th first scan signal SCi.

The third transistor T3 may include a source S3 connected to the j-th initial line RLj, a drain D3 connected to the first electrode AE (see FIG. 7) of the light emitting element OLED, and a gate G3 receiving the i-th second scan signal SSi. The j-th initial line RLj may receive an initial voltage Vr.

The capacitor Cst may store voltage difference of various values according to input signals. For example, the capacitor Cst may store a voltage corresponding to a difference between a voltage transmitted from the second transistor T2 and the first power voltage ELVDD.

FIG. 7 shows a schematic cross-sectional view of a display module DM-1 including the pixel PXij-1 described with reference to FIGS. 5 and 6.

The display module DM-1 according to an embodiment may include a display panel DP-1 and a light control layer OSL. The display panel DP-1 may include a base layer BL, a circuit layer DP-CL, an element layer DP-OL, and a thin film encapsulation layer TFE.

The base layer BL-1 according to an embodiment may include a first organic layer PI1, a first barrier layer BA1, a second organic layer PI2, and a second barrier layer BA2 which are sequentially stacked along an emitting direction of light generated from the light emitting element OLED.

Each of the first and second organic layers PI1 and PI2 may include an organic material. For example, first and second organic layers PI1 and PI2 may include at least one of polyimide (PI), polyethylene naphthalate, polyethylene terephthalate, polyarylate, polycarbonate, polyetherimide, and polyethersulfone.

The first and second barrier layers BA1 and BA2 may include an inorganic material. For example, the barrier layer BI may include at least one of aluminum oxide, titanium oxide, silicon oxide, silicon nitride, silicon oxynitride, zirconium oxide, and hafnium oxide. The first and second barrier layers BA1 and BA2 may prevent oxygen or moisture introduced through the base layer BL-1 from penetrating into pixels.

The display panel DP-1 according to an embodiment may further include a compensation electrode MTL-1 disposed in the base layer BL-1. The compensation electrode MTL-1 may be connected to the second electrode CE of the light emitting element OLED in the peripheral area NAA (see FIG. 5). Descriptions thereof will be provided below.

A light blocking pattern BML may be disposed on the base layer BL-1. The light blocking pattern BML may serve a function such as shielding. The light blocking pattern BML may block an electric potential due to polarization between insulating layers disposed on the light blocking pattern BML from affecting the first to seventh transistors T1 to T3 (see FIG. 6). The light blocking pattern BML according to an embodiment may include molybdenum.

The first insulating layer 10 may be disposed on the base layer BL-1 to cover the light blocking pattern BML. The first insulating layer 10 may be an inorganic layer and/or an organic layer, and have a single-layered or multi-layered structure. The first insulating layer 10 may include at least one of aluminum oxide, titanium oxide, silicon oxide, silicon nitride, silicon oxynitride, zirconium oxide, and hafnium oxide.

The first semiconductor pattern of the first transistor T1 may be disposed on the first insulating layer 10. The first semiconductor pattern may include a silicon semiconductor. FIG. 7 only shows a portion of the first semiconductor pattern, and the first semiconductor pattern may be further disposed in another region of the pixel PXij-1 (see FIG. 6). The first semiconductor pattern may have different electrical properties according to a doping. The first semiconductor pattern may include a doped region and a non-doped region. The doped region may be doped with an N-type dopant or a P-type dopant. A P-type transistor may include a doped area which is doped with a P-type dopant. A N-type transistor may include a doped area which is doped with a N-type dopant.

The source S1, the active μl, and the drain D1 of the first transistor T1 may be formed from the first semiconductor pattern. The source S1 and the drain D1 of the first transistor T1 may be formed to be spaced apart each other with the active μl therebetween.

The second insulating layer 20 may be disposed on the first semiconductor pattern and may overlap the gate G1 in a plan view. The second insulating layer 20 may include at least one of aluminum oxide, titanium oxide, silicon oxide, silicon nitride, silicon oxynitride, zirconium oxide, and hafnium oxide.

A gate G1 of the first transistor T1 may be disposed on the second insulating layer 20. The gate G1 may be a portion of a metal pattern. The gate G1 of the first transistor T1 may overlap the active μl of the first transistor T1 in a plan view. In the process of doping of the first semiconductor pattern, the gate G1 of the first transistor T1 may function as a mask.

The third insulating layer 30 may be disposed on the second insulating layer 20 and cover the source S1, the drain D1, and the gate G1. In the embodiment, the third insulating layer 30 may be an organic layer.

The source electrode SE and the drain electrode DE may be disposed on the third insulating layer 30. The drain electrode DE may be connected to the drain D1 of the first transistor T1 through a contact hole passing through the third insulating layer 30.

The source electrode SE may be connected to the source S1 of the first transistor T1 and the light blocking pattern BML through a contact hole passing through at least one of the first insulating layer 10 and the third insulating layer 30. According to an embodiment, the light blocking pattern BML may receive signals applied to the source S1 of the first transistor T1 to form a sync structure below a semiconductor pattern.

The fourth insulating layer 40 may be disposed on the third insulating layer 30 and may cover the source electrode SE and the drain electrode DE. The fifth insulating layer 50 may be disposed on the fourth insulating layer 40. The fourth insulating layer 40 and the fifth insulating layer 50 may be organic layers. One of the fourth insulating layer 40 and the fifth insulating layer 50 may be omitted.

An electrode of the capacitor Cst (see FIG. 6) may be disposed on the third insulating layer 30, and another electrode of the capacitor Cst (see FIG. 6) may be disposed on the fourth insulating layer 40.

Components of the light emitting element OLED may be disposed on the fifth insulating layer 50. The first electrode AE of the light emitting element OLED may be disposed on the fifth insulating layer 50. The pixel defining film PDL may be disposed on the fifth insulating layer 50. An opening OP exposing at least a portion of the first electrode AE may be defined in the pixel defining film PDL. In the embodiment, the pixel defining film PDL may have a color and include a light absorbing material. For example, the color of the pixel defining film PDL may be black.

The first to third transistors T1 to T3 (see FIG. 6) connected to the light emitting element OLED may constitute one pixel PXij-1 (see FIG. 6).

The opening OP of the pixel defining film PDL may define a light emitting region PXA. For example, the pixels PXij-1 (see FIG. 6) of the display panel DP-1 may be arranged in a regular manner in a plan view. A region in which the pixels PXij-1 (see FIG. 6) are disposed may be defined as an active area AA, and the active area AA may include multiple light emitting regions PXA and a non-light emitting region NPXA adjacent to the light emitting regions PXA. The light emitting region PXA may be surrounded by a non-light emitting region NPXA.

The first electrode AE may be disposed on the fifth insulating layer 50. The first electrode AE may be connected to the source electrode SE through a contact hole passing through the fifth insulating layer 50.

The light emitting element OLED according to an embodiment may further include a hole control layer (not illustrated) disposed between the first electrode AE and the light emitting pattern EML. The hole control layer may be commonly disposed in the light emitting region PXA and the non-light emitting region NPXA. A common layer such as a hole control layer may be commonly formed in the pixels PXij-1 (see FIG. 6). The hole control layer may include a hole transport layer and a hole injection layer.

The light emitting pattern EML may be disposed between the first electrode AE and the second electrode CE. The light emitting pattern EML may overlap the opening OP in a plan view. The light emitting pattern EML may be separately formed in each of the pixels PXij-1 (see FIG. 6).

Although the light emitting pattern EML patterned and disposed in an opening OP is shown as an embodiment, the light emitting pattern EML may be commonly disposed in the pixels PXij-1 (see FIG. 6), and the light emitting pattern EML may generate white light or blue light. The light emitting pattern EML may have a multi-layer structure.

The light emitting element OLED according to an embodiment may further include an electron control layer (not illustrated) disposed between the second electrode CE and the light emitting pattern EML. The electron control layer may include an electron transport layer and an electron injection layer.

The second electrode CE may be disposed on the light emitting pattern EML. The electron control layer and the second electrode CE may be commonly disposed in the pixels PXij-1 (see FIG. 6). Accordingly, the second electrode CE according to the disclosure may be disposed over the entire active area AA and peripheral area NAA (see FIG. 5).

The thin film encapsulation layer TFE may be disposed on the second electrode CE. The thin film encapsulation layer TFE may be commonly disposed on the pixels PXij-1. In the embodiment, the thin film encapsulation layer TFE may cover (e.g., directly cover) the second electrode CE. The thin film encapsulation layer TFE may include a first thin film inorganic layer 61, a thin film organic layer 62, and a second thin film inorganic layer 63. However, the disclosure is not limited thereto, and the thin film encapsulation layer TFE may further include multiple inorganic layers and organic layers.

The first thin film inorganic layer 61 may contact the second electrode CE. The first thin film inorganic layer 61 may prevent external moisture or oxygen from penetrating into the light emitting pattern EML. For example, the first thin inorganic layer 61 may include silicon nitride, silicon oxide, or a combination thereof. The first thin inorganic layer 61 may be formed through a deposition process.

The thin film organic layer 62 may be disposed on the first thin film inorganic layer 61 and contact the first thin film inorganic layer 61. The thin film organic layer 62 may provide a flat surface on the first thin film inorganic layer 61.

The second thin film inorganic layer 63 may be disposed on the thin film organic layer 62 and cover the thin film organic layer 62. The second thin film inorganic layer 63 may be stably formed on a relatively flat surface compared to the first thin film inorganic layer 61. The second thin film inorganic layer 63 may prevent moisture or oxygen from being introduced into the light emitting pattern EML. The second thin film inorganic layer 63 may include silicon nitride, silicon oxide, or a combination thereof. The second thin film inorganic layer 63 may be formed through a deposition process.

The light control layer OSL may include division patterns BM1 and BM2, color filters CF, color control layers CCF, a barrier rib BMW, and multiple capping layers 71 and 72. The light control layer OSL according to an embodiment may further include an additional division pattern BP disposed on the thin film encapsulation layer TFE. Components included in the light control layer OSL will be described in the order from the base substrate BS, for convenience of description.

A first division pattern BM1 may be disposed on the base substrate BS. The first division pattern BM1 may overlap the pixel defining film PDL in a plan view.

The first division pattern BM1 may define a first opening in which the color filters CF are disposed. An opening may be defined based on the optical properties of the first division pattern BM1. For example, the first division pattern BM1 may be formed together with a color filter CF, and the first opening may not be formed in the region where the first division pattern BM1 and the color filter CF are formed.

A second division pattern BM2 may be disposed on the first division pattern BM1. A second opening overlapping the first opening defined in the first division pattern BM1 in a plan view may be defined in the second division pattern BM2. An area of the first opening may be greater than an area of the second opening in a plan view. The second division pattern BM2 may be a black matrix that blocks most of the entire wavelength band of visible light.

The display module DM-1 according to an embodiment may include the first and second division patterns BM1 and BM2 which are stacked to prevent different light controlled by each of the color control layers CCF from being color-mixed. Accordingly, the display panel DP-1 may have improved color reproducibility.

The color filters CF may be disposed on the base substrate BS. The color filters CF may include pigments and/or dyes absorbing different wavelength bands. For example, the first color filter may be a red color filter, the second color filter may be a green color filter, and the third color filter may be a blue color filter.

The color filters CF may be disposed in corresponding openings among the openings defined by the first and second division patterns BM1 and BM2.

A first capping layer 71 may be disposed on the base substrate BS and cover the color filters CF. The first capping layer 71 may be commonly disposed on the color filters CF. The first capping layer 71 may include an inorganic material. For example, the first capping layer 71 may include at least one of silicon oxide, silicon nitride, and silicon oxy nitride.

The color control layers CCF may be disposed on the first capping layer 71. At least one of the color control layers CCF may absorb source light generated from the light emitting element OLED and generate light having a color different from that of the source light. One of the color control layers CCF may transmit incident source light.

The color control layers CCF generating light of a color different from that of the source light may include a base resin and quantum dots mixed (or dispersed) in the base resin. Other color control layers CCF may include scattering particles (scatterers). The scattering particles may be titanium oxide or silica-based nanoparticles.

The second capping layer 72 may individually seal the color control layers CCF. For example, in a region overlapping the second division pattern BM2, the first capping layer 71 and the second capping layer 72 may contact each other to seal the corresponding color control layers CCF.

The second capping layer 72 may include an inorganic material. For example, the second capping layer 72 may include at least one of silicon oxide, silicon nitride, and silicon oxy nitride.

The barrier rib BMW may be disposed on the second capping layer 72. The barrier rib BMW may be disposed on the second capping layer 72 in an area overlapping the second division pattern BM2 in a plan view. A portion of the barrier rib BMW may be covered by the second capping layer 72. The barrier rib BMW may include a material that absorbs light.

The light control layer OSL according to an embodiment may be spaced apart from the display panel DP-1 by a space (predetermined or selectable). The space may be provided as an empty space or may be filled with an inert gas.

The light control layer OSL according to the embodiment may further include an additional division pattern BP. The additional division pattern BP may be disposed on the thin film encapsulation layer TFE. The additional division pattern BP may overlap the barrier rib BMW in a plan view. However, the disclosure is not limited thereto, and the additional division pattern BP may be omitted.

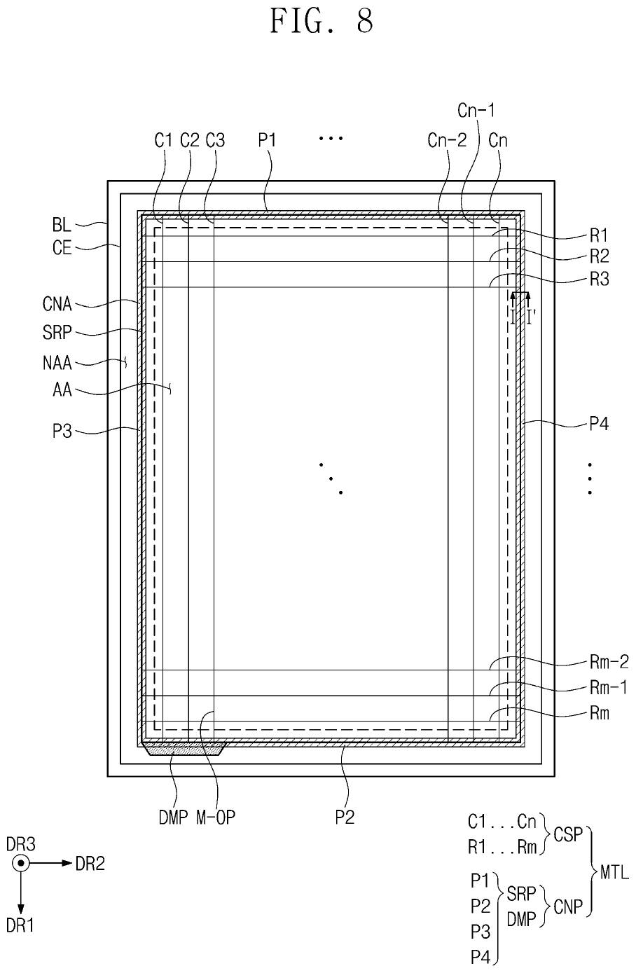

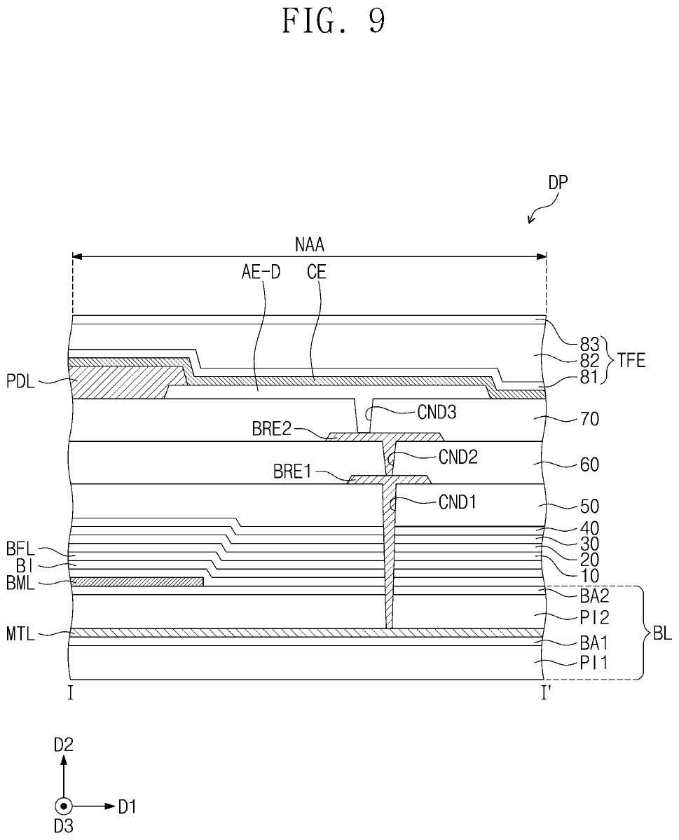

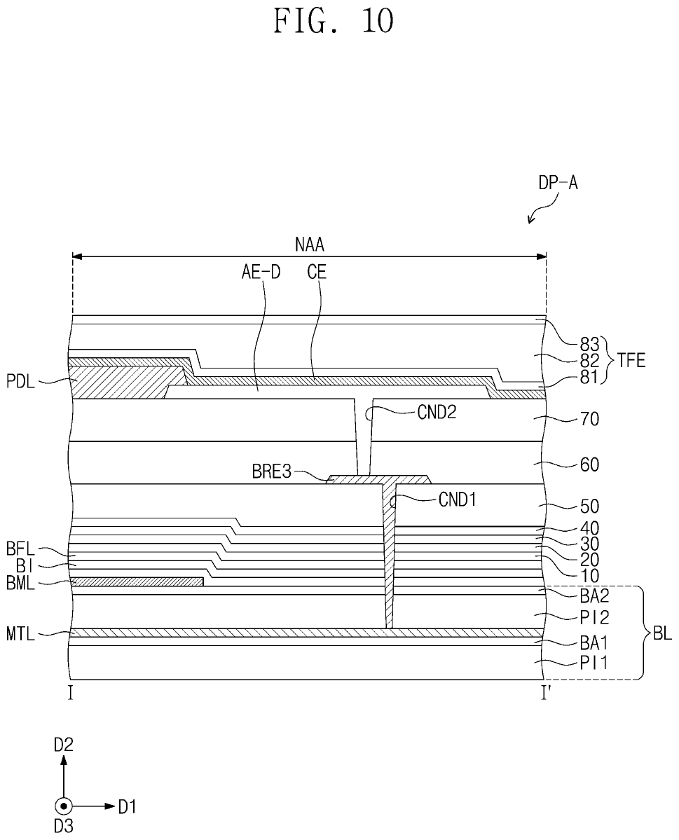

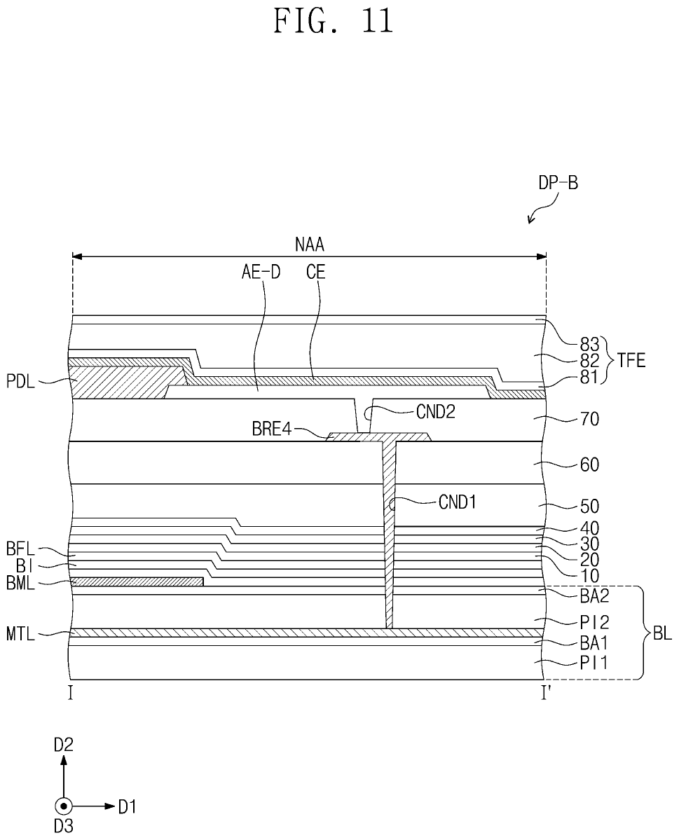

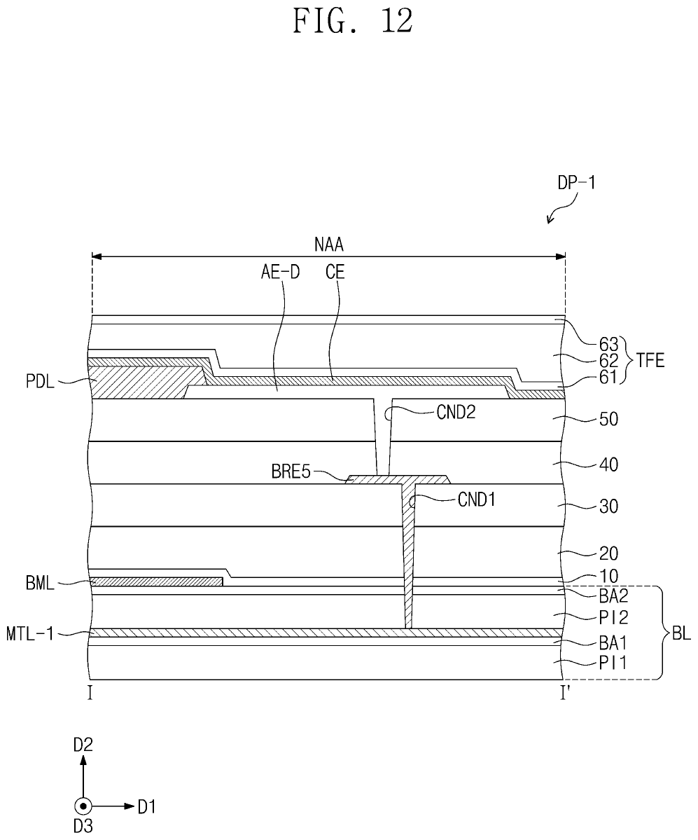

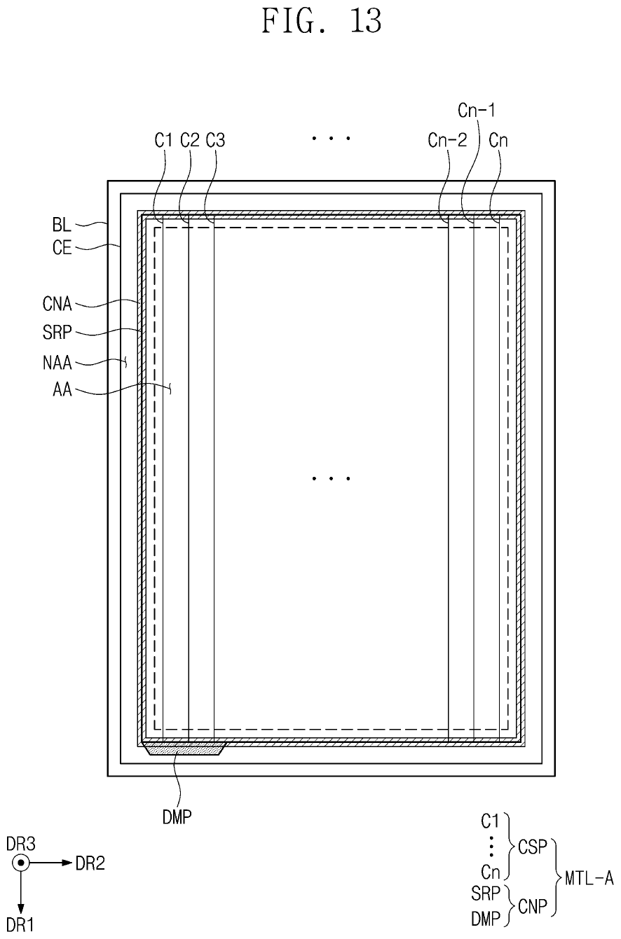

FIG. 8 is a plan view of a compensation electrode disposed on a base layer according to an embodiment of the disclosure. FIG. 9 is a schematic cross-sectional view of a display panel, taken along line I′-I of FIG. 8 according to an embodiment of the disclosure. FIG. 10 is a schematic cross-sectional view of a display panel, taken along line I′-I of FIG. 8 according to an embodiment of the disclosure. FIG. 11 is a schematic cross-sectional view of a display panel, taken along line I′-I of FIG. 8 according to an embodiment of the disclosure. FIG. 12 is a schematic cross-sectional view of a display panel, taken along line I′-I of FIG. 8 according to an embodiment of the disclosure.

A compensation electrode MTL which will be described with reference to FIG. 8 may be applied to the display panel DP described with reference to FIGS. 2 to 4 and the display panel DP-1 described with reference to FIGS. 5 to 7.

The display panel which will be described with reference to FIGS. 9 to 11 may correspond to the display panel DP described with reference to FIG. 4, and the display panel which will be described with reference to FIG. 12 may correspond to the display panel DP-1 described with reference to FIG. 7.

Referring to FIGS. 8 and 9, the display panel DP according to an embodiment may include a compensation electrode MTL disposed in the base layer BL. FIG. 8 shows a shape of the compensation electrode MTL disposed in the base layer BL in a plan view.

The compensation electrode MTL according to an embodiment may include a compensation pattern CSP disposed in the active area AA and a contact pattern CNP disposed in the peripheral area NAA.

The compensation pattern CSP may include first patterns C1 to Cn and second patterns R1 to Rm. Each of the first patterns C1 to Cn may extend in the first direction DR1 and may be spaced apart from each other in the second direction DR2. Each of the second patterns R1 to Rm may extend in the second direction DR2 and may be spaced apart from each in the first direction DR1. The compensation pattern CSP may have pattern openings M-OP defined by the corresponding first patterns C1 to Cn and the second patterns R1 to Rm cross each other, and disposed in the active area AA. According to an embodiment, the compensation pattern CSP may have a mesh shape or a grid shape in the active area AA in a plan view.

The contact pattern CNP may include a main pattern SRP and a sub pattern DMP. The main pattern SRP may be disposed in the peripheral area NAA and surround the active area AA in a plan view. The main pattern SRP according to an embodiment may have a rectangular shape in a plan view corresponding to a border between the active area AA and the peripheral area NAA.

The main pattern SRP may include first to fourth sides P1 to P4. Each of the first and second sides P1 and P2 may extend in the second direction DR2 and may be spaced apart from each other in the first direction DR1 with the active area AA therebetween. Each of the third and fourth sides P3 and P4 may extend in the first direction DR1 and may be spaced apart from each other in the second direction DR2 with the active area AA therebetween. An end of each of the third and fourth sides P3 and P4 may be connected to an end of each of the first and second sides P1 and P2, and another end of each of the third and fourth sides P3 and P4 may be connected to another end of each of the first and second sides P1 and P2.

An end of each of the first patterns C1 to Cn may extend to the peripheral area NAA and may be connected to the first side P1 of the main pattern SRP. Another end of each of the first patterns C1 to Cn may extend to the peripheral area NAA and may be connected to the second side P2 of the main pattern SRP. An end of each of the second patterns R1 to Rm may extend to the peripheral area NAA and may be connected to the third side P3 of the main pattern SRP. Another end of each of the second patterns R1 to Rm may extend to the peripheral area NAA and may be connected to the fourth side P4 of the main pattern SRP.

The contact pattern CNP according to an embodiment may further include a sub pattern DMP protruding from a portion of the main pattern SRP. The sub pattern DMP may protrude from a portion of the main pattern SRP in a direction away from the active area AA.

In the direction in which the portion of the main pattern SRP extends, for example, in the second direction DR2 in which the second side P2 extends, a width of the sub pattern DMP may decrease along the first direction DR1 from the active area AA. Accordingly, the sub pattern DMP may have a trapezoidal shape in a plan view.

The sub pattern DMP may be disposed adjacent to a pad providing the second power voltage ELVSS (FIG. 3B) among pads disposed on the display panel DP. FIG. 8 shows that the sub pattern DMP protrudes from a portion of the second side P2, but the disclosure is not limited thereto, and the sub pattern DMP is not limited to any one position as long as it is disposed adjacent to the pad providing the second power voltage ELVSS (FIG. 3B).

For convenience of description, the compensation electrode MTL is described to be divided into a compensation pattern CSP disposed in the active area AA and a contact pattern CNP disposed in the peripheral area NAA, but the compensation pattern CSP and the contact pattern CNP may be integral with each other.

The compensation electrode MTL according to an embodiment may include a lower layer, an intermediate layer, and an upper layer which are sequentially stacked. A thickness of the intermediate layer may be greater than a thickness of the lower layer and a thickness of the upper layer. For example, a thickness of each of the lower layer and the upper layer may be in a range of about 200 μm to about 600 μm, and a thickness of the intermediate layer may be in a range of about 4000 μm to about 8000 μm. Each of the lower and upper layers may include titanium, and the intermediate layer may include aluminum.

Referring to FIG. 9, the base layer BL may include a first organic layer PI1, a first barrier layer BA1, a second organic layer PI2, and a second barrier layer BA2 which are sequentially stacked. The compensation electrode MTL according to an embodiment may be disposed in the base layer BL. For example, the compensation electrode MTL may be disposed on the first barrier layer BA1 and covered by the second organic layer PI2.

In the embodiment, the compensation electrode MTL may be electrically connected to the second electrode CE in the peripheral area NAA. The second electrode CE may be formed over the entire peripheral area NAA as well as active area AA. In FIG. 8, a region in which the compensation electrode MTL and the second electrode CE are connected in the peripheral area NAA is shown as a connection region CNA.

The display panel DP according to an embodiment may further include a first compensation connection electrode BRE1, a second compensation connection electrode BRE2, and a dummy electrode AE-D disposed in the peripheral area NAA.

The second electrode CE may be connected to the compensation electrode MTL in the peripheral area NAA through the first compensation connection electrode BRE1, the second compensation connection electrode BRE2, and the dummy electrode AE-D. The second electrode CE may be covered by the thin film encapsulation layer TFE.

The first compensation connection electrode BRE1 and the first connection electrode CNE1 described with reference to FIG. 4 may be disposed on a same layer. For example, the first compensation connection electrode BRE1 may be disposed on the fifth insulating layer 50 and covered by the sixth insulating layer 60. The first compensation connection electrode BRE1 may be connected to the compensation electrode MTL through a first compensation contact hole CND1 passing through the first to fifth insulating layers 10 to 50, the buffer layer BFL, the barrier layer BI, the second barrier layer BA2, and the second organic layer PI2.

The second compensation connection electrode BRE2 and the second connection electrode CNE2 described with reference to FIG. 4 may be disposed on a same layer. For example, the second compensation connection electrode BRE2 may be disposed on the sixth insulating layer 60 and covered by the seventh insulating layer 70. The second compensation connection electrode BRE2 may be connected to the first compensation connection electrode BRE1 through a second compensation contact hole CND2 passing through the sixth insulating layer 60.

The dummy electrode AE-D may be an electrode additionally patterned to electrically connect the second electrode CE extending to the peripheral area NAA and the compensation electrode MTL. The dummy electrodes AE-D and the first electrode AE described with reference to FIG. 4 may include a same material and may be formed through a same process. Accordingly, the dummy electrodes AE-D may be disposed on the seventh insulating layer 70 and be exposed from the pixel defining film PDL. The dummy electrode AE-D may be connected to the second compensation connection electrode BRE2 through a third compensation contact hole CND3 passing through the seventh insulating layer 70.

The second electrode CE according to an embodiment may contact the dummy electrode AE-D in the peripheral area NAA. Accordingly, the second electrode CE may be connected to the compensation electrode MTL in the peripheral area NAA through the first compensation connection electrode BRE1, the second compensation connection electrode BRE2, and the dummy electrode AE-D. However, the disclosure is not limited thereto, and the second electrode CE may be directly connected to the compensation electrode MTL in the peripheral area NAA.

The compensation electrode MTL may serve to store the second power voltage ELVSS (see FIG. 3B) provided to the second electrode CE. The second electrode CE may have a multi-layer structure as it is connected to the compensation electrode MTL, and accordingly, the display panel DP may provide a light emitting element OLED including the second electrode CE having low resistance.

In the display panel DP according to the disclosure, as the second electrode CE is electrically connected to the compensation electrode MTL disposed in a mesh or grid shape over the entire active area AA, a uniform second power voltage ELVSS may be supplied to pixels over the entire active area AA. Accordingly, the display panel DP having uniform luminance over the entire active area AA may be provided.

As the second electrode CE and the compensation electrode MTL are connected in the peripheral area NAA, a separate space and process (e.g., a drilling process using a laser, etc.) for connecting the second electrode CE and the compensation electrode MTL in the active area AA may be omitted.

Referring to FIG. 10, a display panel DP-A according to an embodiment may include a third compensation connection electrode BRE3 and a dummy electrode AE-D disposed in the peripheral area NAA. The stack structure of the display panel DP-A in the active area AA and a stack structure of the display panel DP described with reference to FIG. 4 may be same.

The second electrode CE may be connected to the compensation electrode MTL in the peripheral area NAA through the third compensation connection electrode BRE3 and the dummy electrode AE-D. The second electrode CE may be covered by the thin film encapsulation layer TFE.

The third compensation connection electrode BRE3 and the first connection electrode CNE1 described with reference to FIG. 4 may be disposed on a same layer. For example, the third compensation connection electrode BRE3 may be disposed on the fifth insulating layer 50 and covered by the sixth insulating layer 60. The third compensation connection electrode BRE3 may be connected to the compensation electrode MTL through a first compensation contact hole CND1 passing through the first to fifth insulating layers 10 to 50, the buffer layer BFL, the barrier layer BI, the second barrier layer BA2, and the second organic layer PI2.

The dummy electrode AE-D may be an electrode additionally patterned to electrically connect the second electrode CE extending to the peripheral area NAA and the compensation electrode MTL. The dummy electrodes AE-D and the first electrode AE described with reference to FIG. 4 may include a same material and may be formed through a same process. Accordingly, the dummy electrodes AE-D may be disposed on the seventh insulating layer 70 and be exposed from the pixel defining film PDL. The dummy electrode AE-D may be connected to the third compensation connection electrode BRE3 through the second compensation contact hole CND2 passing through the sixth insulating layer 60 and the seventh insulating layer 70.

The second electrode CE according to an embodiment may contact the dummy electrode AE-D in the peripheral area NAA. Accordingly, the second electrode CE may be connected to the compensation electrode MTL in the peripheral area NAA through the third compensation connection electrode BRE3 and the dummy electrode AE-D.

Referring to FIG. 11, a display panel DP-B according to an embodiment may include a fourth compensation connection electrode BRE4 and a dummy electrode AE-D disposed in the peripheral area NAA. The stack structure of the display panel DP-B in the active area AA and the stack structure of the display panel DP described with reference to FIG. 4 may be same.

The second electrode CE may be connected to the compensation electrode MTL in the peripheral area NAA through the fourth compensation connection electrode BRE4 and the dummy electrode AE-D.

The fourth compensation connection electrode BRE4 and the second connection electrode CNE2 described with reference to FIG. 4 may be disposed on a same layer. For example, the fourth compensation connection electrode BRE4 may be disposed on the sixth insulating layer 60 and covered by the seventh insulating layer 70. The fourth compensation connection electrode BRE4 may be connected to the compensation electrode MTL through a first compensation contact hole CND1 passing through the first to sixth insulating layers 10 to 60, the buffer layer BFL, the barrier layer BI, the second barrier layer BA2, and the second organic layer PI2.

The dummy electrode AE-D may be an electrode additionally patterned to electrically connect the second electrode CE extending to the peripheral area NAA and the compensation electrode MTL. The dummy electrodes AE-D and the first electrode AE described with reference to FIG. 4 may include a same material and may be formed through a same process. Accordingly, the dummy electrodes AE-D may be disposed on the seventh insulating layer 70 and be exposed from the pixel defining film PDL. The dummy electrode AE-D may be connected to the fourth compensation connection electrode BRE4 through the second compensation contact hole CND2 passing through the seventh insulating layer 70.

The second electrode CE according to an embodiment may contact the dummy electrode AE-D in the peripheral area NAA. Accordingly, the second electrode CE may be connected to the compensation electrode MTL in the peripheral area NAA through the fourth compensation connection electrode BRE4 and the dummy electrode AE-D.

Referring to FIG. 12, a display panel DP-1 according to an embodiment may include a fifth compensation connection electrode BRE5 and a dummy electrode AE-D disposed in the peripheral area NAA. The stack structure of the display panel DP-1 in the active area AA and the stack structure of the display panel DP-1 described with reference to FIG. 7 may be same.

The second electrode CE may be connected to a compensation electrode MTL-1 in the peripheral area NAA through the fifth compensation connection electrode BRE5 and the dummy electrode AE-D. The second electrode CE may be covered by the thin film encapsulation layer TFE.

The fifth compensation connection electrode BRE5 and the source electrode SE and the drain electrode DE described with reference to FIG. 7 may be disposed on a same layer. For example, the fifth compensation connection electrode BRE5 may be disposed on the third insulating layer 30 and covered by the fourth insulating layer 40. The fifth compensation connection electrode BRE5 may be connected to the compensation electrode MTL-1 through the first compensation contact hole CND1 passing through the first to third insulating layers 10 to 30, the second barrier layer BA2, and the second organic layer PI2.

The dummy electrode AE-D may be an electrode additionally patterned to electrically connect the second electrode CE extending to the peripheral area NAA and the compensation electrode MTL-1. The dummy electrodes AE-D the first electrode AE described with reference to FIG. 7 may include a same material and may be formed through a same process. Accordingly, the dummy electrodes AE-D may be disposed on the fifth insulating layer 50 and be exposed from the pixel defining film PDL. The dummy electrode AE-D may be connected to the fifth compensation connection electrode BRE5 through the second compensation contact hole CND2 passing through the fourth insulating layer 40 and the fifth insulating layer 50.

The second electrode CE according to an embodiment may contact the dummy electrode AE-D in the peripheral area NAA. Accordingly, the second electrode CE may be connected to the compensation electrode MTL-1 in the peripheral area NAA through the fifth compensation connection electrode BRE5 and the dummy electrode AE-D.

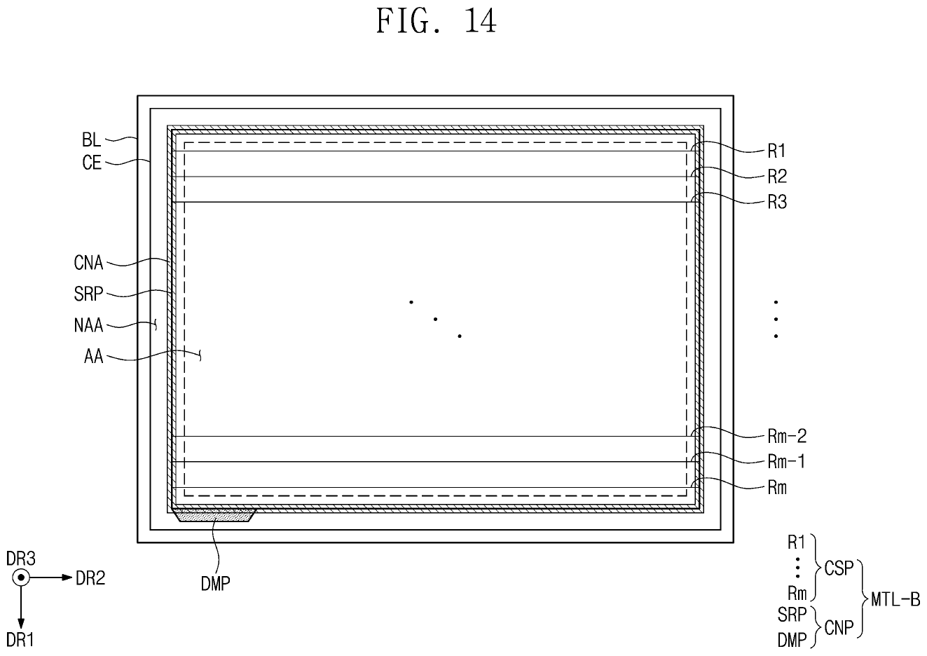

FIG. 13 is a plan view of a compensation electrode disposed on a base layer according to an embodiment of the disclosure. FIG. 14 is a plan view of a compensation electrode disposed on a base layer according to an embodiment of the disclosure. The same/similar reference numerals are used for the same/similar components as those described in FIG. 8, and duplicate descriptions are omitted.

Referring to FIG. 13, a compensation electrode MTL-A according to an embodiment may include a compensation pattern CSP disposed in the active area AA and a contact pattern CNP disposed in the peripheral area NAA.

The base layer BL according to an embodiment may include long sides extending in the vertical direction, for example, the first direction DR1, and short sides extending in a horizontal direction, for example, the second direction DR2.

The compensation pattern CSP may include first patterns C1 to Cn. Each of the first patterns C1 to Cn may extend in the first direction DR1 and may be spaced apart from each other in the second direction DR2. The first patterns C1 to Cn may extend in a direction in which a long side of the base layer BL extends. According to an embodiment, the compensation pattern CSP may have multiple lines in the active area AA.

The contact pattern CNP may include a main pattern SRP and a sub pattern DMP. The main pattern SRP may be disposed in the peripheral area NAA and surround the active area AA. The main pattern SRP according to an embodiment may have a rectangular shape corresponding to a border between the active area AA and the peripheral area NAA in a plan view.

An end of each of the first patterns C1 to Cn may extend to the peripheral area NAA and may be connected to a side of the main pattern SRP. The side of the main pattern SRP may extend in the second direction DR2 in which the short side of the base layer BL extends. Another end of each of the first patterns C1 to Cn may extend to the peripheral area NAA and be connected to another side of the main pattern SRP. The another side may be spaced apart from the side in the first direction DR1 with the active area AA therebetween.

The contact pattern CNP according to an embodiment may include a sub pattern DMP protruding from a portion of the main pattern SRP. The sub pattern DMP may protrude from a portion of the main pattern SRP in a direction away from the active area AA. The sub pattern DMP according to an embodiment may be disposed in a region adjacent to the short side of the base layer BL.

Referring to FIG. 14, a compensation electrode MTL-B according to an embodiment may include a compensation pattern CSP disposed in the active area AA and a contact pattern CNP disposed in the peripheral area NAA.

The base layer BL according to an embodiment may include long sides extending in a horizontal direction, for example, the second direction DR2, and short sides extending in a vertical direction, for example, the first direction DR1.

The compensation pattern CSP may include first patterns R1 to Rm. Each of the first patterns R1 to Rm may extend in the second direction DR2 and be spaced apart from each other in the first direction DR1. The first patterns R1 to Rm may extend in a direction in which the long side of the base layer BL extends. According to an embodiment, the compensation pattern CSP may have multiple lines in the active area AA.

The contact pattern CNP may include a main pattern SRP and a sub pattern DMP. The main pattern SRP may be disposed in the peripheral area NAA and surround the active area AA. The main pattern SRP according to an embodiment may have a rectangular shape corresponding to a border between the active area AA and the peripheral area NAA in a plan view.

An end of each of the first patterns R1 to Rm may extend to the peripheral area NAA and be connected to a side of the main pattern SRP. The side of the main pattern SRP may extend in the first direction DR1 in which the short side of the base layer BL extends. Another end of each of the first patterns R1 to Rm may extend to the peripheral area NAA and be connected to another side of the main pattern SRP. The another side may be spaced apart from the side in the second direction DR2 with the active area AA therebetween.

The contact pattern CNP according to an embodiment may include a sub pattern DMP protruding from a portion of the main pattern SRP. The sub pattern DMP may protrude from a portion of the main pattern SRP in a direction away from the active area AA. The sub pattern DMP according to an embodiment may be disposed in a region adjacent to the long side of the base layer BL.

In a display panel according to the disclosure, as a cathode of a light emitting element is electrically connected to a compensation electrode disposed in a mesh or grid shape over an entire active area, a uniform power voltage may be supplied to pixels over the entire active area. Accordingly, a display panel having uniform luminance may be provided.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments.

What is claimed is:

1. A display panel comprising:
a base layer including an active area and a peripheral area disposed adjacent to the active area;
a compensation electrode disposed in the base layer and including:
a compensation pattern disposed in the active area; and
a contact pattern electrically connected to the compensation pattern and disposed in the peripheral area;
at least one transistor disposed on the base layer; and
a light emitting element including:
a first electrode electrically connected to the at least one transistor;
a second electrode disposed on the first electrode; and
a light emitting pattern disposed between the first electrode and the second electrode,
wherein the second electrode is disposed in the active area and the peripheral area, and is electrically connected to the contact pattern in the peripheral area.

2. The display panel of claim 1, wherein the contact pattern surrounds the active area in a plan view.

3. The display panel of claim 1, wherein the compensation pattern comprises first patterns each extending in a first direction and spaced apart from each other in a second direction intersecting the first direction.

4. The display panel of claim 3, wherein the compensation pattern further comprises second patterns each extending in the second direction, intersecting the first patterns, and spaced apart from each other in the first direction.

5. The display panel of claim 4, wherein
an end of each of the first patterns is electrically connected to a first side of the contact pattern, which extends in the second direction,
another end of each of the first patterns is electrically connected to a second side of the contact pattern, which extends in the second direction and is spaced apart from the first side in the first direction,
an end of each of the second patterns is electrically connected to a third side of the contact pattern, which extends in the first direction and is electrically connected to an end of each of the first side and the second side of the contact pattern, and
another end of each of the second patterns is electrically connected to a fourth side of the contact pattern, which extends in the first direction and is electrically connected to another end of each of the first side and the second side of the contact pattern.

6. The display panel of claim 4, wherein the compensation pattern further comprises pattern openings defined by the first patterns and the second patterns, and disposed in the active area.

7. The display panel of claim 1, wherein the contact pattern comprises:
a main pattern surrounding the active area in a plan view; and
a sub pattern protruding from a portion of the main pattern in a direction away from the active area.

8. The display panel of claim 7, wherein a width of the sub pattern in a direction the portion of the main pattern extends decreases along the direction the sub pattern protrudes.

9. The display panel of claim 1, wherein the base layer comprises a first organic layer, a first barrier layer, a second organic layer, and a second barrier layer, which are sequentially stacked.

10. The display panel of claim 9, wherein the compensation electrode is disposed on the first barrier layer and covered by the second organic layer.

11. The display panel of claim 10, wherein each of the first organic layer and the second organic layer comprises polyimide.

12. The display panel of claim 10, wherein each of the first barrier layer and the second barrier layer comprises silicon oxide.

13. The display panel of claim 1, wherein
the compensation electrode comprises a lower layer, an intermediate layer, and an upper layer, which are sequentially stacked, and
a thickness of the intermediate layer is greater than a thickness of the lower layer and a thickness of the upper layer in a thickness direction of the base layer.

14. The display panel of claim 13, wherein
each of the lower layer and the upper layer comprises titanium, and
the intermediate layer comprises aluminum.

15. The display panel of claim 1, further comprising:
a dummy electrode directly contacting the second electrode in the peripheral area,
wherein the dummy electrode and the first electrode are disposed on a same layer.

16. The display panel of claim 15, further comprising:
a first intermediate insulating layer disposed on the transistor; and
a first connection electrode disposed on the first intermediate insulating layer in the active area, and electrically connected to the first electrode and the at least one transistor.

17. The display panel of claim 16, further comprising:
a first compensation connection electrode disposed in the peripheral area, and electrically connected to the dummy electrode and the compensation electrode,
wherein the first compensation connection electrode and the first connection electrode are disposed on a same layer.

18. The display panel of claim 17, further comprising:
a second intermediate insulating layer disposed on the first intermediate insulating layer; and
a second connection electrode disposed on the second intermediate insulation layer in the active area, and electrically connected to the first electrode and the first connection electrode.

19. The display panel of claim 18, further comprising:
a second compensation connection electrode disposed in the peripheral area, and electrically connected to the dummy electrode and the first compensation connection electrode,
wherein the second compensation connection electrode and the second connection electrode are disposed on a same layer.

20. The display panel of claim 1, wherein
the at least one transistor comprises a source, an active, a drain, and a gate overlapping the active in a plan view, and
the display panel further comprises a light blocking pattern overlapping the active in a plan view and disposed on the base layer.
